(19) United States
(12) Patent Application Publication
(10) Pub. No.: US 2017/0046472 A1
(43) Pub. Date: Feb. 16, 2017

(54) COMPUTER-READABLE STORAGE MEDIUM HAVING ELECTRO-STATIC DISCHARGE VERIFICATION PROGRAM STORED THEREIN, INFORMATION PROCESSING APPARATUS, AND METHOD OF VERIFYING ELECTRO-STATIC DISCHARGE

(71) Applicant: FUJITSU LIMITED, Kawasaki-shi (JP)

(72) Inventors: Daichi Shimada, Kawasaki (JP); Masayoshi Hashima, Kawasaki (JP)

(73) Assignee: FUJITSU LIMITED, Kawasaki-shi (JP)

(21) Appl. No.: 15/231,955

(22) Filed: Aug. 9, 2016

(30) Foreign Application Priority Data
Aug. 12, 2015 (JP) 2015-159585

(51) Int. Cl. G06F 17/50; H02H 1/00; G01R 29/12

(52) U.S. Cl. CPC G06F 17/5081; G01R 29/12; G06F 17/5009; H02H 1/0092; G06F 2217/70

(57) ABSTRACT

A charge transfer distance of a charge conducting from a target component to a different component in the verified device is calculated. A region where the calculated charge transfer distance falls within a predetermined value is then obtained. The obtained region is output as an influence range of the electro-static discharge on the target component. According to this configuration, the time of an electro-static discharge verification is reduced.

### CROSS-REFERENCE TO RELATED APPLICATION

This application is based upon and claims the benefit of priority of the prior Japanese Application No. 2015-159585 filed on Aug. 12, 2015 in Japan, the entire contents of which are hereby incorporated by reference.

### FIELD

The present invention relates a non-transitory computer-readable storage medium having an electro-static discharge verification program stored therein, an information processing apparatus, and a method of verifying electro-static discharge.

### BACKGROUND

Electro-static discharge (ESD) may occur when a charged object (e.g., human body) approaches or touches a product, such as a notebook personal computer (PC). The ESD may cause damages to or malfunctions of electric components, such as large scale integrations (LSIs) inside the product. The advancement of size reduction in electric components further intensifies the adverse effects of ESD. Therefore, verifications (checks) of ESD are carried out on products that are being designed and developed (hereinafter referred to as “devices to be verified or verified devices”).

One of such verifications of ESD may be a verification employing an actual product. In a verification employing an actual product, after ESD is induced in a prototype of the actual product, statuses of electric components within the prototype are determined.

In the meantime, virtual product simulators (VPSs) have been developed recently which improve the efficiency of design and development of products by employing three-dimensional models generated by three-dimensional computer-aided design (CAD) techniques. With such virtual product simulators, products are designed through a three-dimensional simulation. In this process, checks on the design rules are carried out to verify whether or not a designed product model is compliant with design rules, without a fabrication of a prototype thereof. One of the design rule checks may include ESD check for the verified device.

In an ESD check through a three-dimensional simulation, as depicted in FIG. 18, a charge transfer distance is calculated which is the distance of transfer of charge induced when a human body or an object touches a product, from where the charge (electro-static) is applied (applied point), to an electric component inside that product. If the calculated charge transfer distance is equal to or greater than a predetermined value, it is determined that the charge will not reach electric component and the electric component will not be affected by the ESD (not problematic). In contrast, if the calculated charge transfer distance is smaller than the predetermined value, it is determined that the charge will reach the electric component and the electric component will be affected by the ESD (problematic).

Conventionally, as depicted in FIG. 3A, a user (designer) sets (designates) multiple applied points of electro-static (charge) one by one, on the screen display of a virtual product simulator as described above. An ESD verification of the entire verified device is carried out by calculating a charge transfer distance from each specified applied point outside the product, to each electric component inside the product, as set forth above, and determining whether or not the calculated charge transfer distance is equal to or greater than a predetermined value.

Patent Document 1: Japanese Patent Laid-open Publication No. 2009-054648

Patent Document 2: Japanese Patent Laid-open Publication No. 2006-337029

Patent Document 3: Japanese Patent Laid-open Publication No. 08-233887

In the situation where applied points are set by the user and an ESD verification is carried out by calculating the charge transfer distances from those applied points, as described above, some of problematic applied points may be missed, as depicted in FIG. 3A. In other words, a verification miss may occur and no applied point that will be influenced by ESD, may not be identified, which may reduce the accuracy of the ESD verification. In order to reduce possible misses, a lot of applied points are required to be set on the entire verified device and a charge transfer distance must be calculated for each applied point. That will extend the time of the ESD verification.

### SUMMARY

Disclosed is a non-transitory computer-readable storage medium having an electro-static discharge verification program stored therein, wherein the discharge verification program causes a computer adapted to verify electro-static discharge in a verified device through a simulation, to execute the following processings (1)-(3) to:

(1) calculate a charge transfer distance of a charge conducting from a target component to a different component in the verified device,
(2) obtain a region where the calculated charge transfer distance falls within a predetermined value, and
(3) output the obtained region as an influence range of the electro-static discharge on the target component.

### BRIEF DESCRIPTION OF THE DRAWINGS

FIG. 1 is a block diagram depicting a functional configuration of one example of an information processing apparatus provided with an electro-static discharge verification function as one embodiment of the present invention;

FIG. 2 is a block diagram depicting one example of hardware configuration of the information processing apparatus embodying the electro-static discharge verification function as one embodiment of the present invention;

FIG. 3A is a drawing illustrating a conventional ESD verification technique where a verification miss occurs;

FIG. 3B is a diagram illustrating an overview of an ESD verification technique of the present embodiment;

FIG. 4 is a diagram illustrating an example of a charge transfer condition for calculating charge transfer paths (transfer distances);

FIG. 5 is a diagram specifically depicting one example of information entered upon an ESD verification of the present embodiment, and how the entry is achieved;

FIG. 6 is a diagram specifically depicting another example of information entered upon an ESD verification of the present embodiment, and how the entry is achieved;

FIG. 7 is a diagram schematically depicting information entered upon an ESD verification of the present embodiment and information display-output by the ESD verification function of the present embodiment;

FIG. 8 is a diagram specifically depicting one example of information display-output by the ESD verification function of the present embodiment;

FIG. 9 is a diagram illustrating functions of an initialization processing unit, an on-surface distance calculation processing unit, and a space distance calculation processing unit in the present embodiment;

FIGS. 10A-10E are diagrams illustrating functions of the initialization processing unit, the on-surface distance calculation processing unit, and the space distance calculation processing unit in the present embodiment;

FIGS. 11A-11C are diagrams illustrating functions of a synthesis processing unit and an interpolation setting processing unit in the present embodiment;

FIG. 12 is a flowchart illustrating a flow of the ESD verification technique by the ESD verification function of the present embodiment;

FIG. 13 is a flowchart illustrating a procedure of initialization processing of the present embodiment;

FIG. 14 is a flowchart illustrating a procedure of charge transfer distance calculation processing of the present embodiment;

FIG. 15 is a flowchart illustrating a procedure of on-surface distance calculation processing of the present embodiment;

FIG. 16 is a flowchart illustrating a procedure of space distance calculation processing of the present embodiment;

FIG. 17 is a flowchart illustrating a procedure of charge transfer distance synthesis processing and interpolation point setting processing of the present embodiment; and

FIG. 18 is a diagram illustrating an ESD verification through a three-dimensional simulation.

### DESCRIPTION OF THE PREFERRED EMBODIMENTS

Hereinafter, embodiments of a computer-readable storage medium having an electro-static discharge verification program stored therein, an information processing apparatus, and a method of verifying electro-static discharge disclosed therein will be described in detail, with reference to the drawings. It is noted, however, that an embodiment described below is merely exemplary, and various modifications and applications of techniques are not excluded. Stated differently, the present embodiment can be practiced in various forms without departing from the spirit thereof. Further, it is also not intended that the drawings include only elements depicted in the drawings, and other functions may be included. The embodiments may be combined as appropriate, unless such combinations contradict each other.

(1) Overview of Electro-Static Discharge Verification Technique of the Present Embodiment

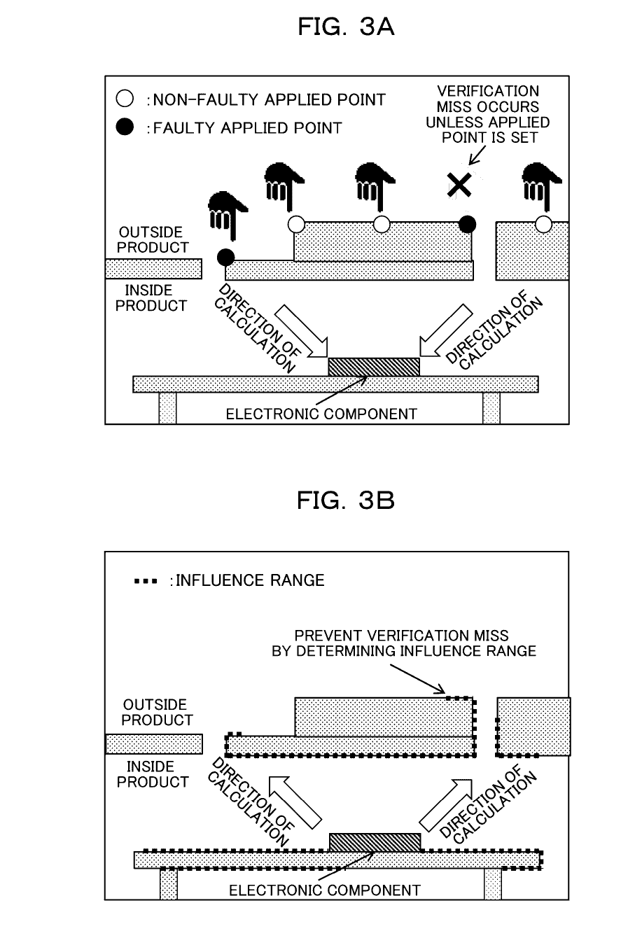

Firstly, referring to FIGS. 3A and 3B, an overview of the present embodiment will be described. FIG. 3A is a drawing illustrating a conventional ESD verification technique where a verification miss occurs, and FIG. 3B is a diagram illustrating an overview of an ESD verification technique of the present embodiment.

Referring to FIG. 3A, as described above, in a conventional ESD verification technique through a three-dimensional simulation, since applied points outside a product are set by a user, a verification miss may occur.

Thus, in the present embodiment, a user designates one or more target components (hereinafter also referred to as “electric components” or “designated electric components”) inside a product (i.e., verified device), on a screen display that displays the product. Once the electric component is designated, a computer (information processing apparatus, virtual product simulator) calculates a charge transfer distance conducting from the designated electric component to a different component in that product, as depicted in FIG. 3B. The computer then obtains a region where the calculated charge transfer distance falls within a predetermined value, and outputs the obtained region, as an influence range of ESD on designated electric component. As depicted in FIG. 3B, the influence range of ESD is display-output on a screen display, for example. When multiple electric components are designated, the computer determines the distribution of charge transfer distances from the respective electric components for synthesis, and display-outputs, as will be described later.

In this manner, the user can see the influence range of ESD of the entire product, including the inside and outside of the product, at a glance by watching a display screen. Hence, the efficiency of an ESD verification is improved and man-hours required for the ESD verification are reduced while preventing any verification miss, i.e., miss of detection of problematic points, in a reliable manner which shortens the time required for the ESD verification. Further, since verification misses are prevented in a reliable manner, a reduction in the accuracy of ESD verification is no more experienced. Additionally, since the computer enables effective checks on anti-ESD measures while the design of the product is being modifying, the interactivity is enhanced and the efficiency of the anti-ESD measures are improved.

Note that in the present embodiment, a path with the minimum voltage attenuation is extracted, as a charge transfer path from a designated electric component to a point of interest (a point on a different component) in the verified device. The voltage attenuation associated with the transfer of charge along the extracted charge transfer path is calculated, as a voltage corresponding to the charge transfer distance from the designated electric component to the point of interest.

Further, in the present embodiment, a determination can be made as of whether charge at the voltage level affecting designated electric component reaches the designated electric component, when electro-static discharge arises on the side of the designated electric component on the border of the influence range that is display-output.

(2) Hardware Configuration of Information Processing Apparatus Embodying Electro-Static Discharge Verification Function of the Present Embodiment

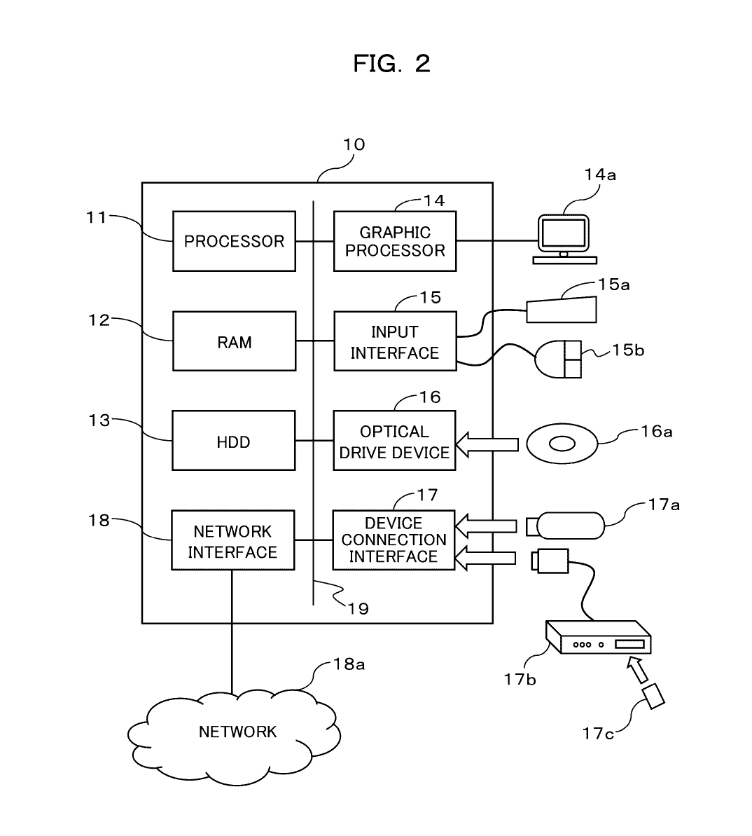

Now referring to FIG. 2, the hardware configuration of an information processing apparatus (computer) 10 embodying an electro-static discharge (ESD) verification function of the present embodiment will be described. FIG. 2 is a block diagram depicting one example of the hardware configuration.

The computer 10 includes a processor 11, a random access memory (RAM) 12, a hard disk drive (HDD) 13, a graphic processor 14, an input interface 15, an optical drive device 16, a device connection interface 17, and a network interface 18, as its elements, for example. These elements 11-18 are configured to be communicative to each other through a bus 19.

The processor (processing unit) 11 controls the entire computer 10. The processor 11 may be a multiprocessor. The processor 11 may be one of a central processing unit (CPU), a micro processing unit (MPU), a digital signal processor (DSP), an application specific integrated circuit (ASIC), a programmable logic device (PLD), a field programmable gate array (FPGA), for example. Otherwise, the processor 11 may be a combination of two or more of a CPU, an MPU, a DSP, an ASIC, a PLD, and an FPGA.

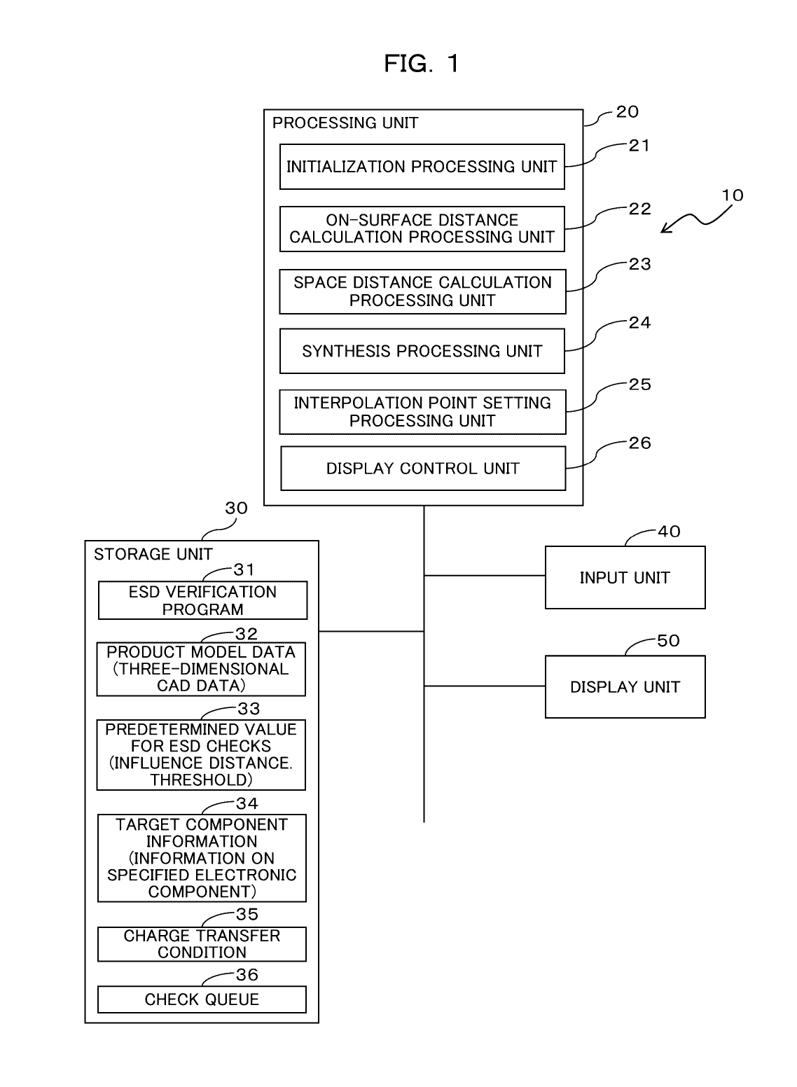

The RAM (storage unit) 12 is used as a main storage device of the computer 10. The RAM 12 stores at least a part of an operating system (OS) program and application programs to be executed by the processor 11. The RAM 12 also stores various types of data used for processing by the processor 11. The application programs may include an ESD verification program (refer to Reference Symbol 31 in FIG. 1) that is to be executed by the processor 11, for achieving the ESD verification function of the present embodiment by the computer 10.

The HDD (storage unit) 13 includes internal disks, and magnetically reads and writes data from and to the disks. The HDD 13 is used as an auxiliary storage device for the computer 10. The HDD 13 stores the OS program, the application program, and the various types of data. Alternatively, a solid state drive (SSD), such as a flush memory, may be used as the auxiliary storage device.

The graphic processor 14 is connected to a monitor 14a. The graphic processor 14 causes an image to be displayed on the screen of the monitor 14a in response to a command from the processor 11. The monitor 14a may be a display device including a cathode ray tube (CRT) or a liquid-crystal display device.

The input interface 15 is connected to a keyboard 15a and a mouse 15b. The input interface 15 sends the processor 11 signals transmitted from the keyboard 15a and the mouse 15b. Note that the mouse 15b is one example of a pointing device, and other pointing devices may be used. Other pointing devices may include a touch panel, a tablet, a touch pad, a trackball, and the like.

The optical drive device 16 reads data that has been recorded on an optical disk 16a by means of laser light, for example. The optical disk 16a is a non-transitory portable storage medium that stores data so as to be readable by means of light reflections. The optical disk 16a may be a digital versatile disc (DVD), a DVD-RAM, a compact disc read only memory (CD-ROM), a CD-Recordable (R)/-Rewritable (RW), and the like.

The device connection interface 17 is a communication interface for connecting peripheral devices to the computer 10. A memory device 17a or a memory reader/writer 17b can be connected to the device connection interface 17, for example. The memory device 17a may be a non-transitory storage medium or a universal serial bus (USB) memory, for example, having a function of communicating with the device connection interface 17. The memory reader/writer 17b writes and reads data to and from the memory card 17c. The memory card 17c is a card-type non-transitory storage medium.

The network interface 18 is connected to a network 18a. Via the network 18a, the network interface 18 sends and receives data to and from other computers or communication devices.

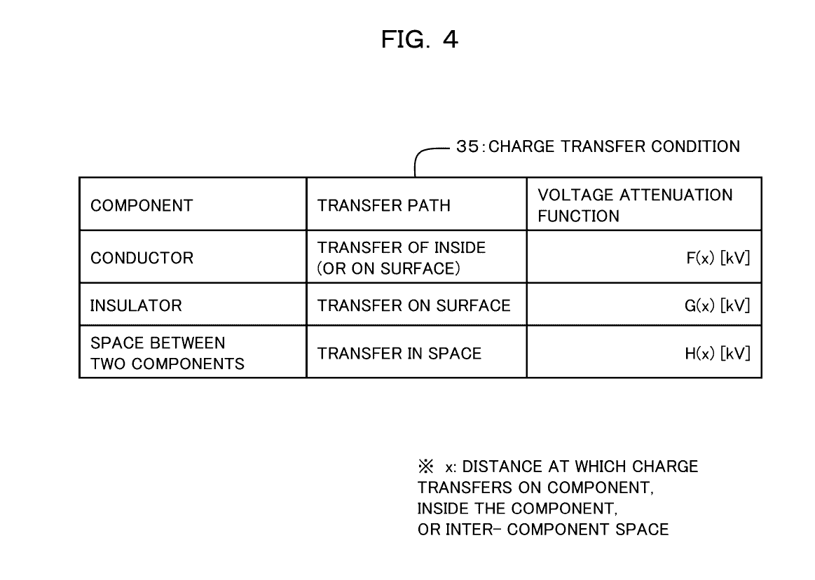

The computer 10 having the hardware configuration as described above can achieve an ESD verification function of the present embodiment that will be described with reference to FIGS. 4-17.

Note that the computer 10 achieves the ESD verification function of the present embodiment, by executing program (e.g., an ESD verification program) recorded in a non-transitory computer-readable storage medium, for example. The program that describes processing to be executed by the computer 10 can be recorded in various types of storage mediums. The program to be executed by the computer 10 may be stored in the HDD 13, for example. The processor 11 loads at least a part of the program in the HDD 13, into the RAM 12, and executes the loaded program.

Alternatively, the program to be executed by the computer 10 (processor 11) may be recorded in a non-transitory portable storage medium, such as the optical disk 16a, the memory device 17a, and the memory card 17c. Once the program stored in the portable storage medium is installed to the HDD 13 under the control by the processor 11, the program can be executed, for example. Alternatively, the processor 11 may read the program directly from the portable storage medium for executing it.

(3) Functional Configuration of Information Processing Apparatus Provided with Electro-Static Discharge Verification Function of the Present Embodiment

Next, referring to FIG. 1, the functional configuration of the information processing apparatus (computer) 10 provided with the electro-static discharge (ESD) verification function of the present embodiment will be described. FIG. 1 is a block diagram depicting one example of the functional configuration thereof.

The computer 10 verifies ESD in a product, which is the device to be verified (verified device), through a simulation, and includes at least functions of a processing unit 20, a storage unit 30, an input unit 40, and a display unit 50, as depicted in FIG. 1, for embodying the functions described above with reference to FIG. 3B.

The processing unit 20 is the processor 11 as depicted in FIG. 2, for example, and functions as an initialization processing unit 21, an on-surface distance calculation processing unit 22, a space distance calculation processing unit 23, a synthesis processing unit 24, an interpolation point setting processing unit 25, and a display control unit 26, which will be described below, by executing the ESD verification program 31 described above.

The storage unit 30 includes the RAM 12 and the HDD 13 as depicted in FIG. 2, for example, and stores and saves various types of information for achieving the ESD verification function. Such various types of information includes product model data 32, a predetermined value for ESD checks 33, target component information 34, a charge transfer condition 35, and a check queue 36, in addition to the ESD verification program 31 described above.

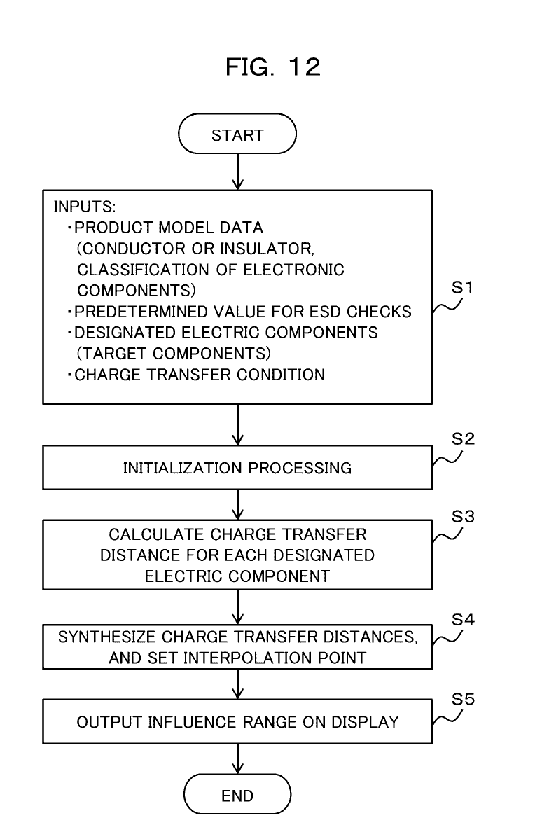

The product model data 32 is three-dimensional CAD data for a product (verified device), which has been generated by a three-dimensional CAD, and includes component model data that is three-dimensional CAD data of various components constructing that product. The product model data 32 includes information indicating whether each component constructing that product is a conductor or an insulator, and information whether or not that component is an electric component that is influenced by electro-static and thus is a target component of the present embodiment (refer to Step S1 in FIG. 12). The product model data 32 is entered from the outside, to the optical disk 16a, the memory device 17a, the memory card 17c, the network 18a, or the like from outside, by a user operating the input unit 40, for example.

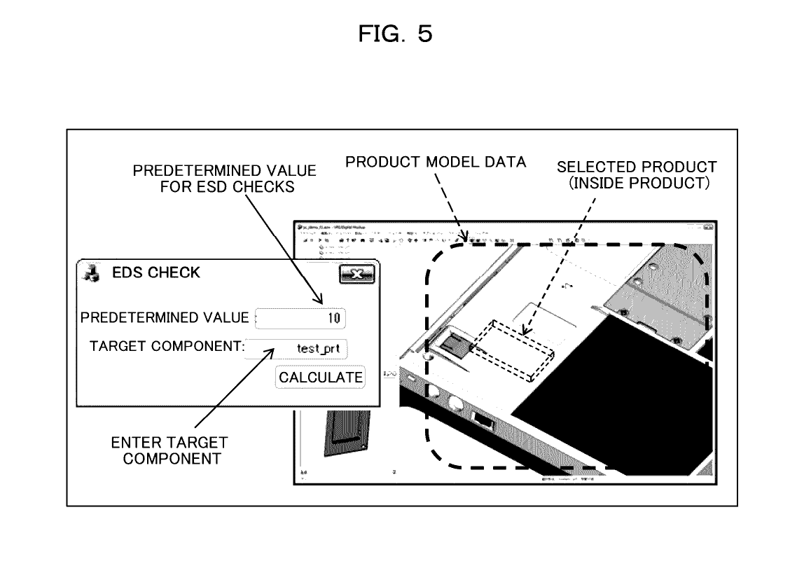

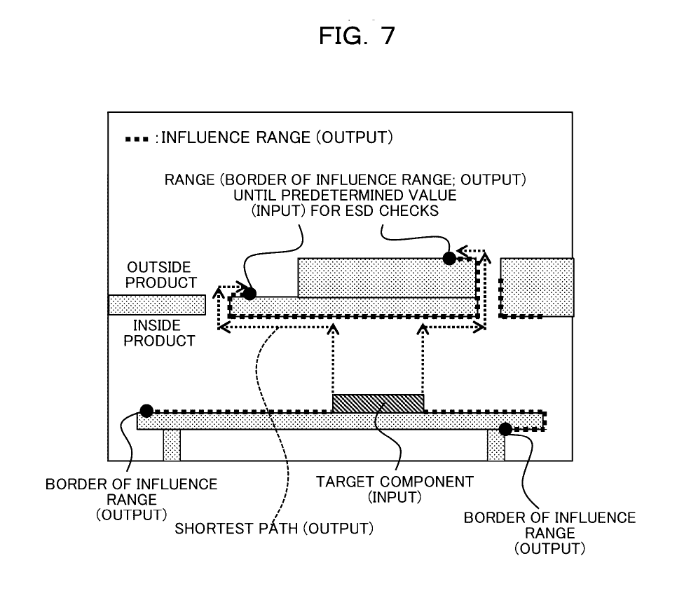

The predetermined value for ESD checks (influence distance, threshold) 33 is a value that defines the border of the influence range (refer to FIGS. 3B, 7, and 8), and is entered and set by the user, as will be described with reference to FIGS. 5 and 7. If electro-static discharge arises somewhere between the border of the influence range and a designated electric component, it is considered that a charge having a voltage level that may affect the designated electric component, reaches the designated electric component. As the predetermined value for ESD checks 33, a voltage corresponding to a charge transfer distance is entered and set. The voltage corresponding to the charge transfer distance is the voltage attenuation associated with the transfer of charge (e.g., in unit of kilovolts (kV)), along a path on which the voltage attenuation of the charge is minimized, from each apex of the designated electric component, to the border of the influence range, for example.

The designated electric component information (target component information) 34 is information about specified designated electric components (target components) entered by the user, as will be described with reference to FIGS. 5-7, and includes information for specifying one or more designated electric components. In the present embodiment, the influence range of ESD of one or more designated electric components identified in the designated electric component information 34, is determined and display-output.

The charge transfer condition 35 is a condition used for calculating a charge transfer path (transfer distance), as will be described later, as depicted in FIG. 4. FIG. 4 is a diagram illustrating an example of the charge transfer condition 35. The charge transfer condition 35 may be entered by the user, or may be supplied from outside through the optical disk 16a, the memory device 17a, the memory card 17c, the network 18a, or the like.

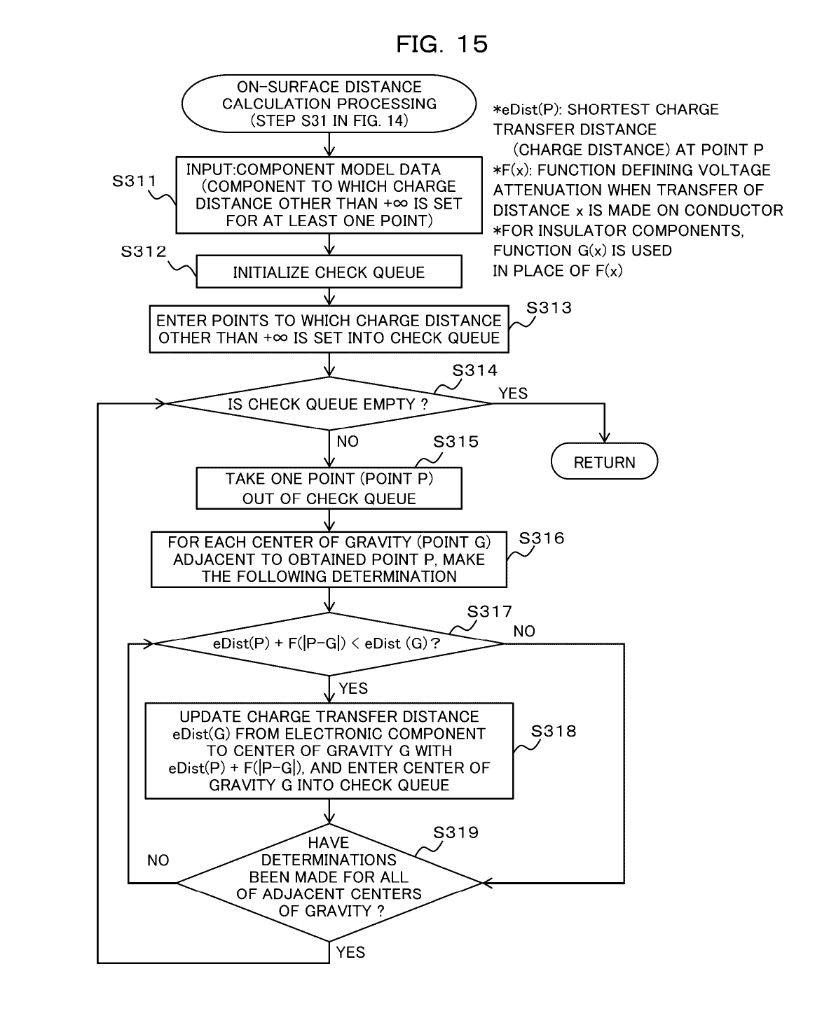

As depicted in FIG. 4, in the case of conductor components, such as electric components and screws, charge transfers inside the conductor component (or along the surface of the conductor component), and the voltage attenuation associated with such a transfer is given by a function F(x) [kV], for example. In the present embodiment, an assumption is made for a conductor component that charge moves along the surface of the conductor component (refer to FIG. 15 and the like). In contrast, in case of insulator component, such as boards and casings, charge moves along the surface of the insulator component, and the voltage attenuation associated with such a transfer is given by a function G(x) [kV], for example. In the space between two components, charge moves in that space, and the voltage attenuation associated with such a transfer is given by a function H(x) [kV], for example.

Note that “x” represents the distance at which charge transfers on the component (along the surface), inside the component, or an inter-component space, and the voltage attenuation functions F(x), G(x), and H(x) are functions of the charge transfer distance “x”. The voltage attenuation functions F(x) and G(x) are each preset for respective conductor components and insulator components, and correspond to a first voltage attenuation function defining a voltage attenuation for the charge transfer distance “x”, which is varied depending on the materials of the components. Similarly, the voltage attenuation function H(x) is preset for spaces between two components, and corresponds to a second voltage attenuation function defining the voltage attenuation at the charge transfer distance “x”, which is varied depending on the temperature and humidity of the space where the charge moves. Since the voltage attenuation of charge moving along a conductor is zero (0) or close to zero, the voltage attenuation function F(x) for a conductor product may be a function that gives a value of zero or close to zero for the charge transfer distance “x”.

In the present embodiment, based on the charge transfer condition 35 including the voltage attenuation functions F(x), G(x), and H(x) as described above, a path with the minimum voltage attenuation is calculated as a charge transfer path and the path length of that transfer path is calculated as the charge transfer distance. In this case, the charge transfer distance can be represented as the voltage corresponding to that charge transfer distance. For example, the voltage attenuation associated with the transfer of charge along the charge transfer path can be calculated as the voltage corresponding to the charge transfer distance. It is determined that charge will not transfer any more when the transfer path reaches a grounded conductor component (conductor component connected to the ground), and the calculation of the transfer path (transfer distance) ends.

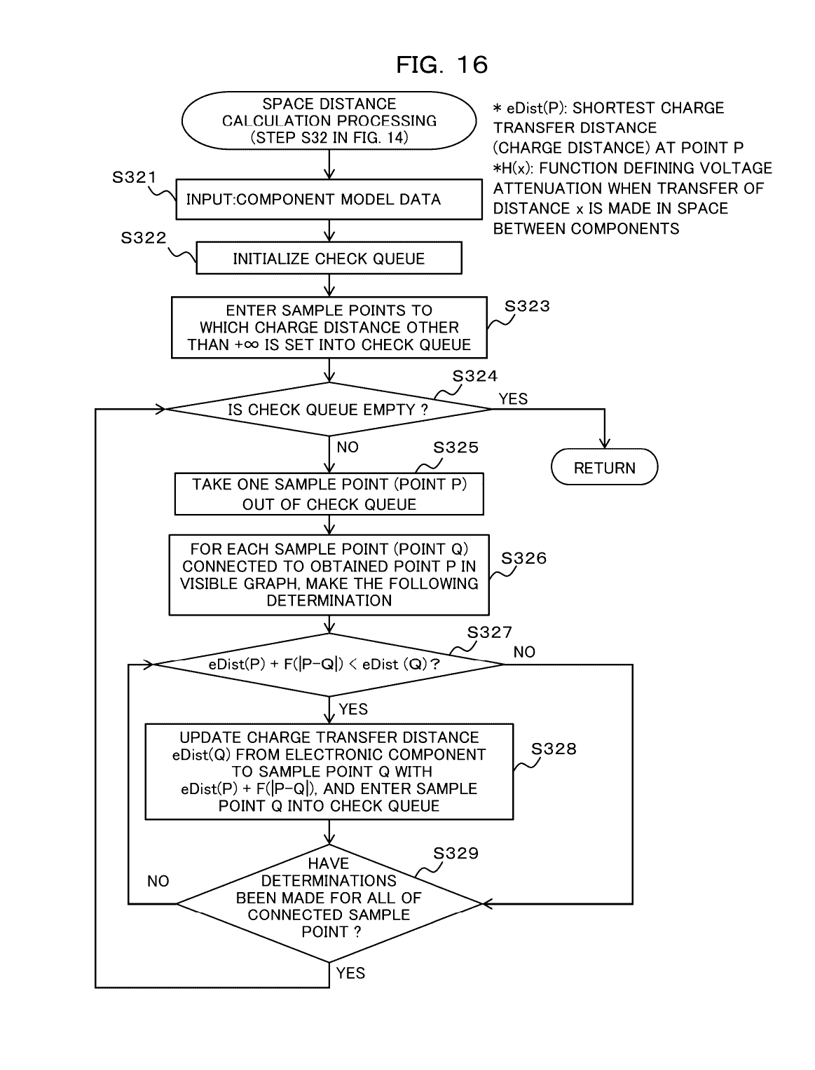

The check queue 36 is initialized at the timing of an execution of on-surface distance calculation processing described later (refer to FIG. 15). To the check queue 36, information specifying an apex or a center of gravity to which a shortest charge transfer distance (charge distance) other than the maximum value (positive Infinity, hereinafter referred to as “+∞”) has been set, is entered for temporarily storing the information. Similarly, the check queue 36 is also initialized at the timing of an execution of distance calculation processing described later (refer to FIG. 16). To the check queue 36, information specifying sample point to which a shortest charge transfer distance (charge distance) other than the maximum value (+∞) has been set, is entered for temporarily storing the information.

The input unit 40 is the keyboard 15a and the mouse 15b, as depicted in FIG. 2, for example, and is operated by the user, to receive the predetermined value for ESD checks 33 and the designated electric component information 34 as depicted in FIGS. 5-7, and to make various instructions for achieving the ESD verification function. In place of the mouse 15b, a touch panel, a tablet, a touch pad, a trackball, or the like may be used.

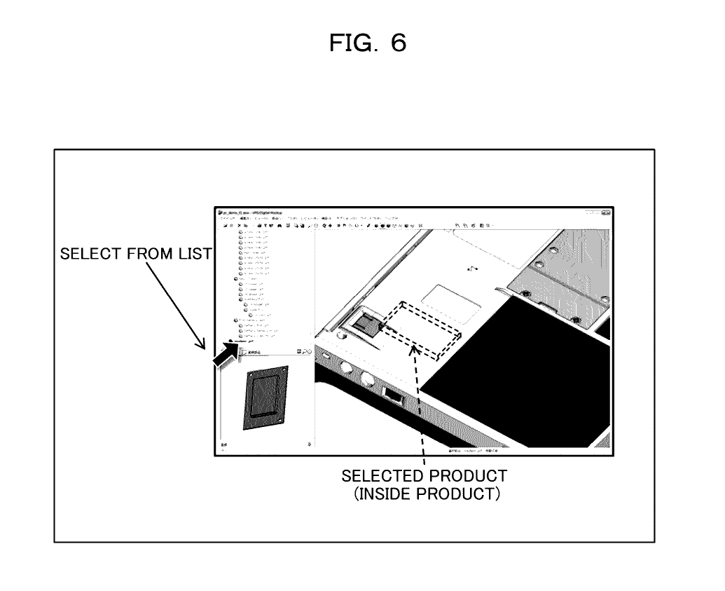

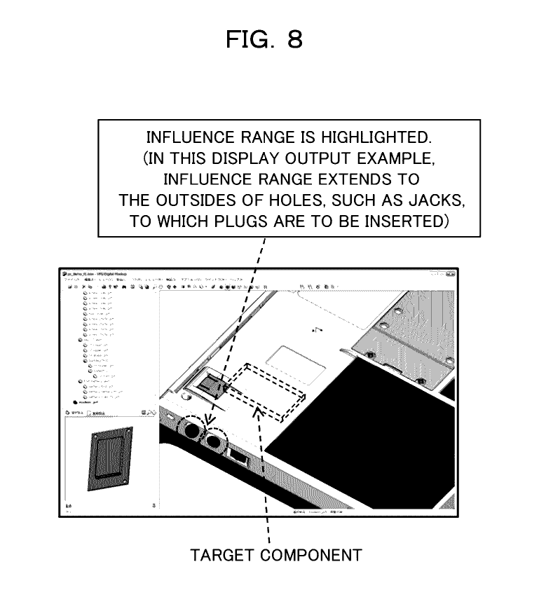

The display unit 50 is the monitor 14a, as depicted in FIG. 2, for example, the display on which is controlled by the display control unit 26 (described later). As depicted in FIGS. 5 and 6, the display unit 50 displays information prompting the user to enter information for achieving the ESD verification function of the present embodiment. As depicted in FIGS. 7 and 8, the display unit 50 also display-outputs the border of the influence range of ESD of one or more designated electric components obtained by the ESD verification function of the present embodiment, and displays various statuses related to the ESD verification procedure. Note that in the present embodiment, while the border of the influence range of ESD or the like is display-output on the display unit 50, the present embodiment is not limited to this and the border of the influence range of ESD may be print-output by a printer or the like.

Here, FIG. 5 is a diagram specifically depicting one example of information entered upon an ESD verification of the present embodiment, and how the entry is achieved. In FIG. 5, a product (i.e., verified device) is displayed on the display unit 50 based on product model data 32, and an ESD check window is displayed as well. The user operates the input unit 40 to enter predetermined value for ESD checks and information specifying target components inside the product (e.g., component names) on the ESD check window. Once a component name is entered, the target component corresponding to those component name, i.e., the selected target component, is emphasized on the display unit 50. For example, the target component is emphasized with a highlight or color. While the target component is selected by entering component name in FIG. 5, a target component may be selected by the user by clicking component displayed on the display unit 50 by operating the mouse 15b.

FIG. 6 is a diagram specifically depicting another example of information entered upon an ESD verification of the present embodiment, and how the entry is achieved. In FIG. 6, component names of candidate components, which can be selected as a target component, are displayed in the list on the display unit 50. A target component may be selected by the user by clicking a component name displayed in the list on the display unit 50 by operating the mouse 15b. In this case, the selected target component is emphasized on the display unit 50.

FIG. 7 is a diagram schematically depicting information entered upon an ESD verification of the present embodiment and information display-output by the ESD verification function of the present embodiment. In the present embodiment, as depicted in FIG. 7, at least predetermined value for ESD checks and a target component are entered and set by the user. Thereafter, based on the predetermined value and target component that are entered and set, an ESD verification of the present embodiment is carried out. Then, as depicted in FIG. 7, an influence range, the border of the influence range, the shortest path from the target component to the border of the influence range (shortest charge transfer path), the path length of that shortest path (also referred to as “shortest distance”, “shortest charge transfer distance”, or “charge distance”) are display-output on the display unit 50. As the shortest distance, a voltage corresponding to that shortest distance is obtained. As the voltage, a charge attenuation associated with charge transfer along that shortest path is obtained, for example. Although no information about the shortest distance is displayed in FIG. 7, the obtained shortest distance (voltage) may be displayed while being related to the display of the shortest path (indicated by the dotted arrows), as information associated with shortest distance.

FIG. 8 is a diagram specifically depicting one example of information display-output by the ESD verification function of the present embodiment. In FIG. 8, a specific example display of the influence range and the border of the influence range is depicted. In FIG. 8, the border of the influence range is emphasized using the dotted line circles. In other words, in the example display output depicted in FIG. 8, the user can visually see that the influence range extends from the target component to the outsides of holes, such as jacks for receiving plugs, only by watching the display unit 50. In this case, the emphasized display may be made, by indicating the surfaces of the component within the influence range in color, or by displaying only components within the influence range. The user can make a determination as of whether charge at a voltage level affecting designated electric component reaches the designated electric component, when electro-static discharge arises on the side of the designated electric component on the border of the influence range, by watching such an emphasized display.

As set forth above, the ESD verification program 31 causes the processing unit 20 (the processor 11) to execute processing by an initialization processing unit 21, an on-surface distance calculation processing unit 22, a space distance calculation processing unit 23, a synthesis processing unit 24, an interpolation point setting processing unit 25, and a display control unit 26, which will be described later.

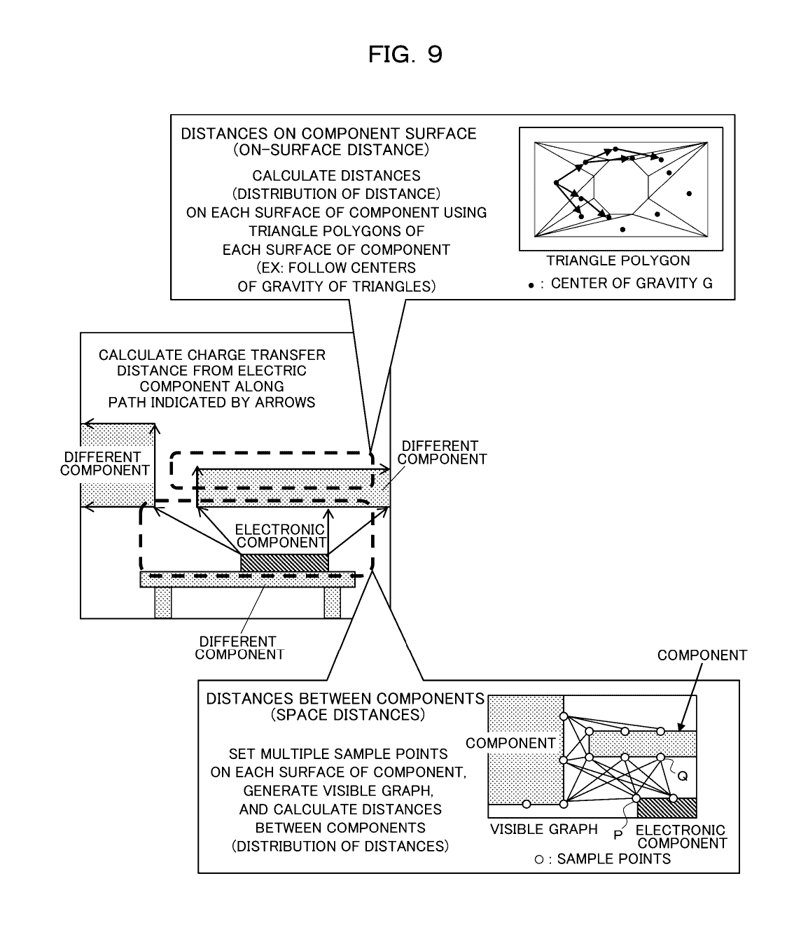

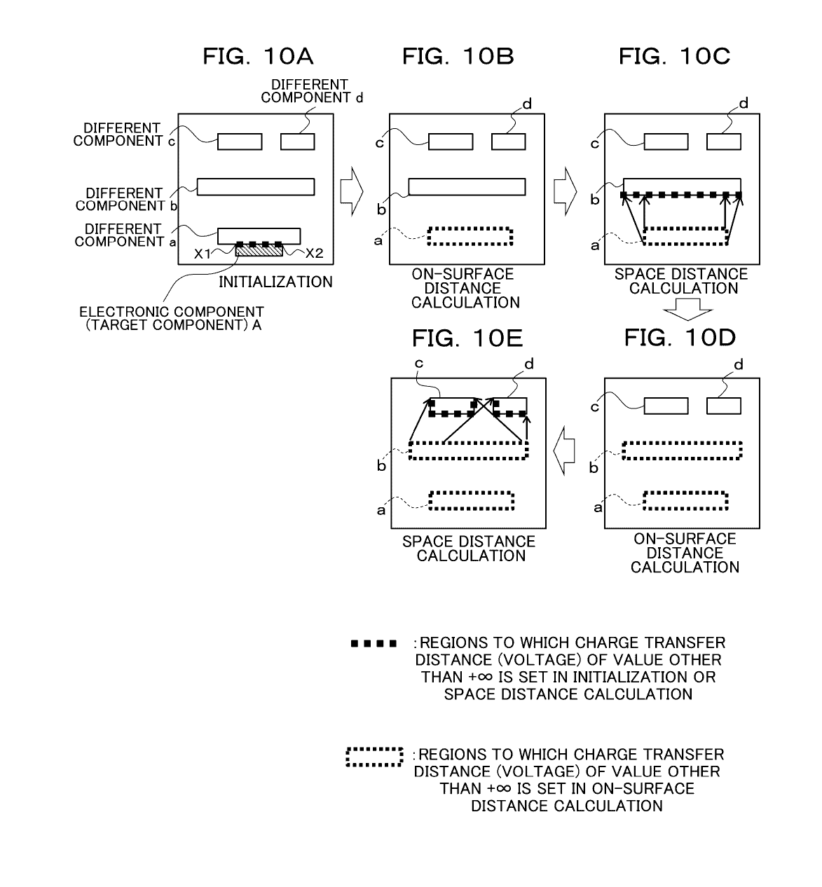

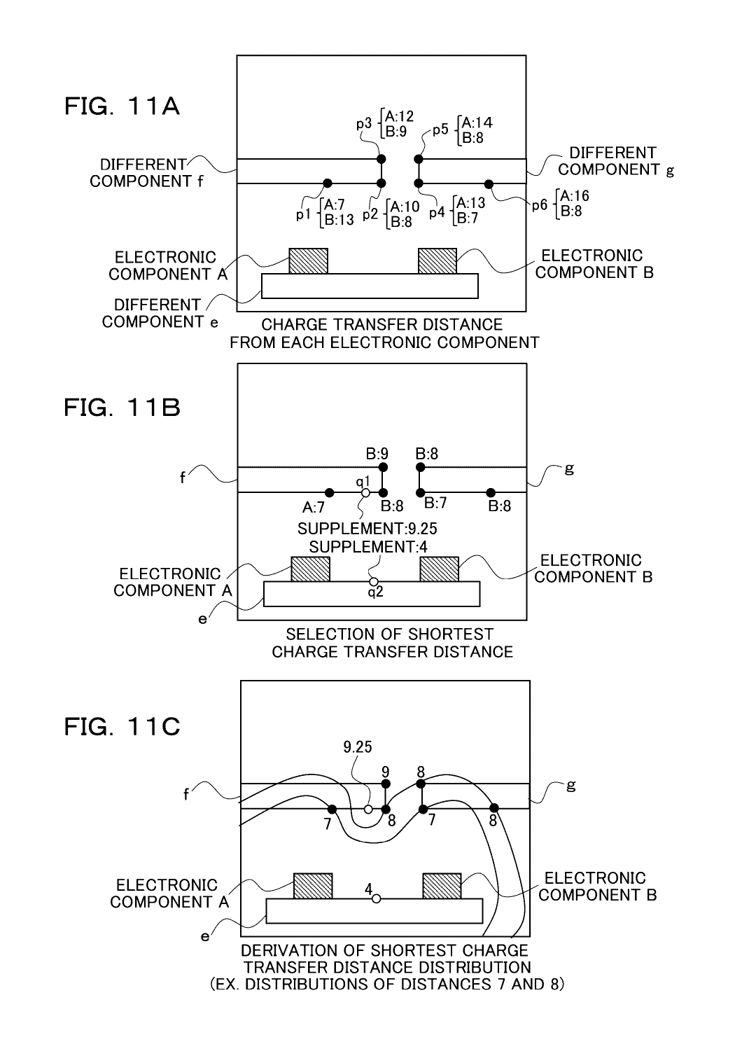

Next, the functions as the initialization processing unit 21, the on-surface distance calculation processing unit 22, the space distance calculation processing unit 23, the synthesis processing unit 24, the interpolation point setting processing unit 25, and the display control unit 26, which are embodied by the processing unit 20 (processor 11), will be described with reference to FIGS. 9-11C. FIGS. 9 and 10A-10E are diagrams illustrating the functions of the initialization processing unit 21, the on-surface distance calculation processing unit 22, and the space distance calculation processing unit 23 in the present embodiment. FIGS. 11A-11C diagrams illustrating the functions of the synthesis processing unit 24 and interpolation setting processing unit 25 in the present embodiment.

The initialization processing unit 21 executes the following processings (a1) through (a4), when an ESD verification of the present embodiment is initiated.

(a1) Multiple sample points are set on one or more designated electric components and multiple different components other than the designated electric components. The sample points may be set by the user, or may be automatically set based on an interval specified by the user. Then, a visible graph connecting between the multiple sample points set on the designated electric components and the multiple different components is generated (refer to the bottom panel in FIG. 9).

(a2) Each different component is divided into multiple meshes. In this case, surfaces of each component are divided into multiple triangle polygons, and the center of gravity G of each triangle is calculated, for example (refer to the top panel in FIG. 9).

(a3) For each of sample points on each different component and the respective centers of gravity G of the multiple meshes on each different component, +∞ (maximum value) is set as the initial value of the charge transfer distance. For example, to the sample points in the component in the bottom panel in FIG. 9, +∞ is set as the initial value. Furthermore, to the centers of gravity G of each triangle polygon on the different components depicted in the top panel in FIG. 9, +∞ is set as the initial value.

(a4) To the apices and sample points on the electric component specified by the user, zero is set as the initial value of the charge transfer distance. To each apex and each center of gravity G on the electric component depicted in the middle panel depicted in FIG. 9, and to sample points on the electric components depicted in the bottom panel in FIG. 9, zero is set as the initial value, for example. Furthermore, in FIG. 10A, points corresponding to the apices of the electric component A and the centers of gravity G within the placement region of the bottom surface (thick dotted line region) of the different component “a”, on which the electric component A is placed, zero is set as the initial value. In FIG. 10A, to Points X1 and X2 corresponding to the apices of the electric component A and the centers of gravity G within the different component “a” within the placement region of the bottom surface (thick dotted line region), after +∞ is set in as the initial value in the above-described processing (a3), zero is set in the processing (a4).

The on-surface distance calculation processing unit 22 follows the centers of gravity G of the triangle polygons on the surfaces of each component, to calculate the charge transfer distance along the surfaces of each component, i.e., the on-surface distance, as depicted in the top panel in FIG. 9. For this purpose, the on-surface distance calculation processing unit 22 executes the following processings (b1) through (b5).

(b1) One of points corresponding to the apices on one or more target components (e.g., the above-described points X1 and X2 in FIG. 10A) and the respective centers of gravity G of the plurality of meshes, is selected to which a value other than +∞ (initial value of zero for the first time) is set as the charge transfer distance, as a point of interest (first point of interest P) on each of the different components. When the processing has just been initiated, the first point of interest P is selected among points to which an initial value of zero has been set. Note that information specifying the points to which a value other than +∞ is set as the charge transfer distance, which are candidates for the first point of interest P, is queued into the check queue 36, and the first point of interest P is selected by taking the information related to the first point of interest P, out of the check queue 36.

(b2) One of centers of gravity G adjacent to the selected first point of interest P is extracted as a subsequent first point of interest (refer to the top panel in FIG. 9).

(b3) A first sum of the charge transfer distance eDist(P) set to the first point of interest P, and the first voltage attenuation associated with transfer from the first point of interest P to the subsequent first point of interest G, is calculated. Here, eDist(P) is the voltage corresponding to the shortest charge transfer distance at the point P. The first voltage attenuation associated with transfer from the first point of interest P to the subsequent first point of interest G is calculated based on the first voltage attenuation function F(x) or G(x) defining the voltage attenuation in accordance with charge transfer distance. Specifically, when the component where the point of interest is located is a conductor, the first voltage attenuation associated with transfer from the first point of interest P to the subsequent first point of interest G is calculated as F(|P−G|) and thus the first sum is eDist(P)+F(|P−G|). Otherwise, when the component where the point of interest is located is an insulator, the first voltage attenuation associated with transfer from the first point of interest P to the subsequent first point of interest G is calculated as G(|P−G|) and the first sum is eDist(P)+G(|P−G|).

(b4) It is determined whether or not the first sum eDist(P)+F(|P−G|) or eDist(P)+G(|P−G|) calculated in the above-described processing (b3) is less than the first voltage eDist(G) corresponding to the charge transfer distance that has been set to the subsequent first point of interest G (the initial value is +∞ for the first time).

(b5) If the first sum is less than the first voltage eDist(G), the first voltage eDist(G) set to the subsequent first point of interest G is updated with the first sum eDist(P)+F(|P−G|) or eDist(P)+G(|P−G|), and the subsequent first point of interest G is entered into the check queue 36. Otherwise, if the first sum is equal to or greater than the first voltage eDist(G), the on-surface distance calculation processing unit 22 returns to the above-described processing (b2).

The above-described processings (b2) through (b5) are repeatedly executed until processing in the above-described processing (b2) is executed on all of the centers of gravity G adjacent to the first point of interest P. The above-described processings (b1) through (b5) are repeatedly executed until no information about a candidate for the first point of interest P is queued in the check queue 36.

The space distance calculation processing unit 23 generates a visible graph based on the sample points that have been set on the surfaces of the components, to calculate charge transfer distances between the components, i.e., space distances, as depicted in the bottom panel in FIG. 9. For this purpose, the space distance calculation processing unit 23 executes the following processings (c1) through (c5).

(c1) One of the apices on the one or more target components and the plurality of sample points is selected, to which a value other than +∞ (initial value of zero for the first time) is set as the charge transfer distance, as a point of interest (second point of interest P) on each of the different components. When the processing has just been initiated, the second point of interest P is selected among points to which an initial value of zero has been set. Information specifying the points to which a value other than +∞ is set as the charge transfer distance, which are candidates for the second point of interest P, is queued into the check queue 36, and the second point of interest P is selected by taking the information related to the second point of interest P, out of the check queue 36.

(c2) One of the sample points connected to the selected second point of interest P in the visible graph is selected as a subsequent second point of interest Q (refer to the bottom panel in FIG. 9). The second point of interest P and the subsequent second point of interest Q each correspond to the points P and Q in FIG. 9, for example.

(c3) A second sum of the charge transfer distance eDist(P) set to the second point of interest P, and the second voltage attenuation associated with transfer from the second point of interest P to the subsequent second point of interest Q, is calculated. Here, the second voltage attenuation associated with transfer from the second point of interest P to the subsequent second point of interest Q is calculated based on the second voltage attenuation function H(x) defining the voltage attenuation in accordance with charge transfer distance that has been preset for each inter-component space. In other words, the second voltage attenuation associated with transfer from the second point of interest P to the subsequent second point of interest Q is calculated as H(|P−Q|), and the second sum is eDist(P)+H(|P−Q|).

(c4) It is determined whether or not the second sum eDist(P)+H(|P−Q|) calculated in the above-described processing (c3) is less than the second voltage eDist(Q) corresponding to the charge transfer distance that has been set to the subsequent second point of interest Q (the initial value is +∞ for the first time).

(c5) If the second sum is less than the second voltage eDist(Q), the second voltage eDist(Q) set to the subsequent second point of interest Q is updated with the second sum eDist(P)+H(|P−Q|) and the subsequent second point of interest Q is entered into the check queue 36. Otherwise, if the second sum is equal to or greater than the second voltage eDist(Q), the space distance calculation processing unit 23 returns to the above-described processing (c2).

The above-described processings (c2) through (c5) are repeatedly executed until the processing is executed on all of the samples point connected to the second point of interest P in the above-described processing (c2). Further, the above-described processings (c1) through (c5) are repeatedly executed until no candidate information for the second point of interest P queued in the check queue 36.

The processing unit 20 repeatedly executes the processing by the on-surface distance calculation processing unit 22 and the space distance calculation processing unit 23, until neither the first voltage eDist(G) nor the second voltage eDist(Q) is updated any more. A specific example of such repetitions of processing will be described with reference to FIGS. 10A-10E. In FIGS. 10A-10E, the different components “a” and “b” are boards inside the product, whereas different components “c” and “d” are casings of the product, which has holes, such as jacks.

For example, in FIG. 10A, the initialization processing unit 21 executes the above-described processings (a1) through (a4) on the designated electric component (target component) A, and on the different components “a” through “d”. As a result, the initial value zero for the charge transfer distance is set to apices and sample points on the electric component A, and the initial value zero for the charge transfer distance is set to sample points and the centers of gravity G within the placement region (thick dotted line region) of the electric component A of the bottom surface of the different component “a”. Further, the initial value +∞ for the charge transfer distance is set to sample points and the centers of gravity G on the different components “a” through “d”, which are different from those to which the initial value zero is set.

After the initialization, as depicted in FIG. 10B, initially, the on-surface distance calculation processing unit 22 selects, for the different component “a” on which the electric component A is placed, one of the points corresponding to the apices of the electric component A and the centers of gravity G to which a value other than +∞ (i.e., zero) has been set as the charge transfer distance, as a first point of interest P, and executes the above-described processings (b1) through (b4). As a result, for each center of gravity G on the outer periphery surface of the different component “a”, the first voltage eDist(G) corresponding to the charge transfer distance from the electric component A to that center of gravity G is updated.

Thereafter, as depicted in FIG. 10C, the space distance calculation processing unit 23 executes the above-described processings (c1) through (c4) on the visible graph from each sample point (second point of interest) P on the left and right surfaces and the top surface of the different component “a”, to each sample point on the bottom surface of the different component “b” (subsequent second point of interest) Q. As a result, for each sample point Q on the bottom surface of the different component “b”, the second voltage eDist(Q) corresponding to the charge transfer distance from the electric component A to that sample point Q is updated.

Then, as depicted in FIG. 10D, the on-surface distance calculation processing unit 22 selects, for the different component “b”, one of the points to which a value other than +∞ has been set as the charge transfer distance (the center of gravity G or sample point), as the first point of interest P, and executes the above-described processings (b1) through (b4). As a result, for each center of gravity G on the outer periphery surface of the different component “b”, the first voltage eDist(G) corresponding to the charge transfer distance from the electric component A to that center of gravity G is updated.

As depicted in FIG. 10E, the space distance calculation processing unit 23 then executes the above-described processings (c1) through (c4) on the visible graph from each sample point (second point of interest) P on the top surface of the different component “b”, to each sample point (subsequent second point of interest) Q on the left and right surfaces and the bottom surface of the different component “c” and the left surface and the bottom surface of the different component “d”. As a result, for each sample point Q on the left and right surfaces and the bottom surface of the different component “c” and the left surface and the bottom surface of the different component “d”, the second voltage eDist(Q) corresponding to the charge transfer distance from the electric component A to that sample point Q is updated.

The synthesis processing unit 24 functions when multiple designated electric components (target components) have been specified by the user, and the processing by the initialization processing unit 21, the on-surface distance calculation processing unit 22, and the space distance calculation processing unit 23 has been executed on each designated electric component. The synthesis processing unit 24 selects the shortest transfer distance from multiple charge transfer distances that have been set for each point of multiple sample points and the centers of gravity G of multiple meshes for each designated electric component, and sets the selected shortest transfer distance to each point.

The interpolation point setting processing unit 25 functions when two shortest charge transfer distances that have been set to each of adjacent two points among each point of multiple sample points and the centers of gravity G of multiple meshes match distances from two different designated electric component among the multiple designated electric components. The interpolation point setting processing 25 sets the point at which charge transfer distances from two different designated electric components match on the line connecting those adjacent two points, as an interpolation point.

The processing unit 20 then derives the distribution of the charge transfer distance, based on the shortest transfer distances that have been set to the respective points by the synthesis processing unit 24 and the interpolation point set by the interpolation point setting processing unit 25, and determines and outputs the influence range of ESD on the multiple designated electric components.

Now referring to FIGS. 11A-11C, the functions of the synthesis processing unit 24 and interpolation setting processing unit 25 will be described.

FIG. 11A depicts example results obtained by executing the processing by the initialization processing unit 21, the on-surface distance calculation processing unit 22, and the space distance calculation processing unit 23 on each of the two electric components A and B. In other words, FIG. 11A illustrates examples of shortest charge transfer distances (charge distances; the physical quantity therefor is voltage) that have been set to the respective points (apices, sample points, the centers of gravity) in each of the electric components A and B.

For example, to Point p1 on the different component “f”, the charge distance 7 from the electric component A is set, and the charge distance 13 from the electric component B is set. Additionally, to Point p2 on the different component “f”, the charge distance 10 from the electric component A is set, and the charge distance 8 from the electric component B is set. Furthermore, to Point p3 on the different component “f”, the charge distance 12 from the electric component A is set, and the charge distance 9 from the electric component B is set.

Similarly, to Point p4 on the different component “g”, the charge distance 13 from the electric component A is set, and the charge distance 7 from the electric component B is set. Additionally, to Point p5 on the different component “g”, the charge distance 14 from the electric component A is set, and the charge distance 9 from the electric component B is set. Furthermore, to Point p6 on the different component “g”, the charge distance 16 from the electric component A is set, and the charge distance 8 from the electric component B is set.

FIG. 11B depicts example results of a synthesis by the synthesis processing unit 24 and interpolation point setting by the interpolation point setting processing unit 25, obtained based on charge distances that have been set to the respective points on each of the electric components A and B as depicted in FIG. 11A.

The synthesis processing unit 24 synthesizes the charge distances for each Point p1-p6 of the two electric components A and B, by selecting the shortest transfer distance of the two charge distances set to the electric components A and B and setting the selected shortest transfer distance to each Point p1-p6, as depicted in FIG. 11B.

For example, the charge distance 7 from the electric component A is selected for Point p1 on the different component “f”, the charge distance 8 from the electric component B is selected for Point p2 on the different component “f”, and the charge distance 9 from the electric component B is selected for Point p3 on the different component T. Similarly, the charge distance 7 from the electric component B is selected for Point p4 on the different component “g”, the charge distance 8 from the electric component B is selected for Point p5 on the different component “g”, and the charge distance 8 from the electric component B is selected for Point p6 on the different component “g”.

Further, the interpolation point setting processing unit 25 functions when the respective two shortest transfer distances set to adjacent two points of Points p1-p6 match the distances from the two different electric components A and B. In the example depicted in FIG. 11B, to Point p1 on the different component “f”, the charge distance 7 from the electric component A is set; to Point p2 adjacent to Point p1, the charge distance 8 from the electric component B is set, and the interpolation point setting processing unit 25 functions as follows for Points p1 and p2. In other words, the interpolation point setting processing 25 sets Point q1 on Line p1-p2 connecting two Points p1 and p2, where the charge distances from the two different designated electric components A and B match, as an interpolation point.

Here, as depicted in FIG. 11A, to Point p1, the charge distance 7 from the electric component A and the charge distance 13 from the electric component B are set; to Point p2, the charge distance 10 from the electric component A and the charge distance 8 from the electric component B are set. Here, it is assumed that the voltage of the charge linearly attenuates between Point p1 and Point p2, and the charge distance from the electric component A and the charge distance from the electric component B have the identical value of “9.25”, on Point q1 at which Line p1-p2 is divided to a ratio of 3:1, as depicted in FIG. 11B.

Specifically, the identical value of “9.25” of the charge distance from the electric component A and the charge distance from the electric component B is determined as follow. Here, the distance between Point p1 and Point p2 in FIG. 11A is represented by a constant K, and a position between Point p1 and Point p2 is represented by “x”. The respective charge distances from the electric component A and from the electric component B at each point between Point p1 and Point p2 are represented by yA and yB. In this case, the charge distances yA and yB at a position “x” are given as follows:

Charge distance yA=(10−7)x/K+7

Charge distance yB=(8−13)x/K+13

In this case, the position “x” where the charge distance yA equals the charge distance yB is calculated as follows:

(10−7)x/K+7=(8−13)x/K+13

3x+7K=−5x+13K

x=3K/4

Hence, charge distance yA=charge distance yB=3*3/4+7=37/4=9.25.

The resultant Point q1 is set as an interpolation point (supplement) on Line p1-p2 (refer to “Interpolation: 9.25” in FIG. 11B).

Although not illustrated in FIG. 11A, zero is set to each apex of the respective electric components A and B, as the charge distance. Hence, Point q2 (the intermediate point between the electric components A and B) on the different component “e” on which the two electric components A and B are placed, may be set as an interpolation point (supplement). In the example depicted in FIG. 11B, at the interpolation point q2, the identical value of “4” is set, for example, as the charge distance from the electric component A and the charge distance from the electric component B.

FIG. 11C illustrates an example distribution of the shortest charge transfer distance derived based on the example result of synthesis and the example result of the interpolation point setting, obtained as depicted in FIG. 11B. The processing unit 20 derives the shortest charge transfer distance distribution by connecting points to which the same charge distance (shortest charge transfer distance) is set in the vicinity, based on the charge distances set to Points p1-p6, q1, and q2, as depicted in FIG. 11C. In the example depicted in FIG. 11C, an equal-distance line of the values 7 and 8 that is derived by connecting points to which the same charge distances of 7 and 8 have been set. In this case, the border of the influence range of ESD is obtained by connecting points to which values (influence distances, thresholds) set as the predetermined value for ESD checks 33 have been set.

The display control unit 26 controls the display state of the above-described display unit 50. For example, the display control unit 26 causes information for prompting the user to enter information for achieving the ESD verification function of the present embodiment (refer to FIGS. 5 and 6), to be displayed on the display unit 50. The display control unit 26 also causes the border of the influence range of ESD (refer to FIGS. 7 and 8) for one or more designated electric components obtained by the ESD verification function of the present embodiment, to be displayed on the display unit 50. Similarly, the display control unit 26 causes the shortest charge transfer distance distribution obtained by the ESD verification function of the present embodiment (refer to FIG. 11C), to be displayed on the display unit 50. Further, the display control unit 26 causes various statuses related to the ESD verification procedure, to be displayed on the display unit 50. In place of causing various types of information to be displayed on the display unit 50, the display control unit 26 may function to print-output to a printer and the like.

(4) ESD Verification Procedure by ESD Verification Function of the Present Embodiment

Next, referring to FIGS. 12-17, an ESD verification procedure by the ESD verification function of the information processing apparatus 10 of the present embodiment will be described.

(4-1) Flow of ESD Verification Technique

Firstly, a flow of the ESD verification technique by the ESD verification function of the present embodiment will be described, with reference to the flowchart depicted in FIG. 12 (Steps S1-S5).

For initiating an ESD verification of the present embodiment, initially, information for executing the ESD verification of the present embodiment is entered to the information processing apparatus 10 and saved in the storage unit 30 (Step S1). The information entered in this step includes at least the product model data 32, the predetermined value for ESD checks 33, the designated electric component information 34, and the charge transfer condition 35, which have been described above.

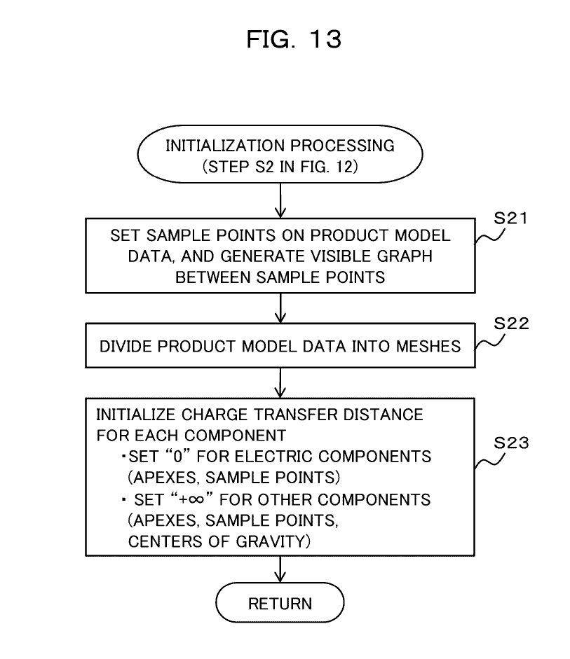

After the entry of the information 32-35, the initialization processing unit 21 executes initialization processing by executing the above-described processings (a1) through (a4) (Step S2). The processing procedure by the initialization processing unit 21 will be described with reference to FIG. 13.

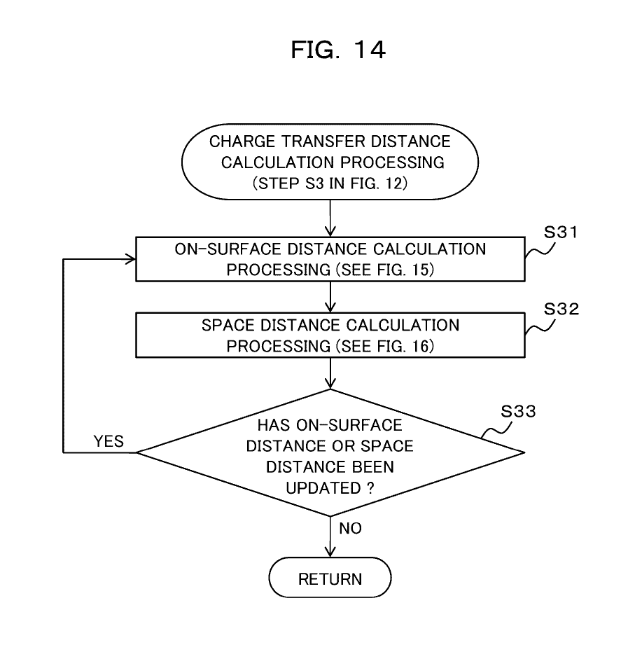

After the initialization processing, for each designated electric component, the on-surface distance calculation processing unit 22 executes the above-described processings (b1) through (b5), and the space distance calculation processing unit 23 executes the above-described processings (c1) through (c5). As a result, the shortest charge transfer distances to the respective points on each designated electric component are calculated, and the calculated shortest charge transfer distances are set to the respective points (Step S3). The processing procedures by the on-surface distance calculation processing unit 22 and the space distance calculation processing unit 23 will be described with reference to FIGS. 14-16.

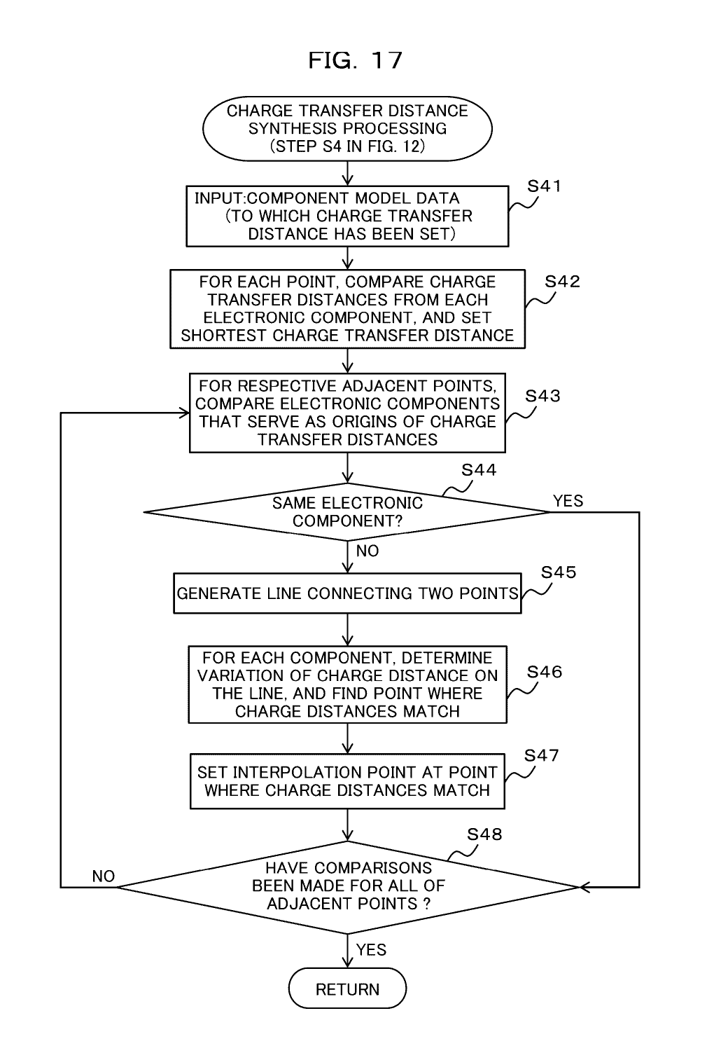

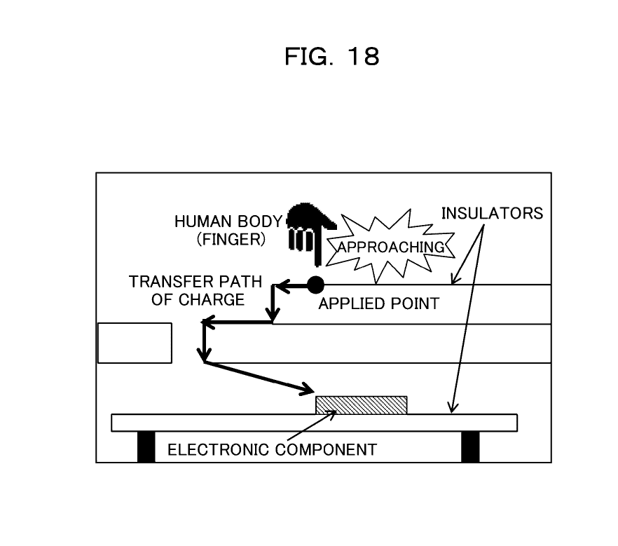

After calculating the shortest charge transfer distances and setting them to the respective points on each designated electric component, the synthesis processing unit 24 selects the shortest transfer distance from the multiple charge transfer distances set to the respective points for the each designated electric component in the procedure described above with reference to FIGS. 11A and 11B, to carry out synthesis of the charge transfer distances (Step S4). In this step, the interpolation point setting processing unit 25 sets an interpolation point and sets the shortest charge transfer distance to that interpolation point, in the procedure described above with reference to FIGS. 11A and 11B. Note that the processing procedures by the synthesis processing unit 24 and the interpolation point setting processing unit 25 will be described with reference to FIG. 17.

Furthermore, the processing unit 20 derives the distribution of the charge transfer distance in the procedure described above with reference to FIG. 11C, based on the shortest transfer distances that have been set to the respective points by the synthesis processing unit 24 and the interpolation point set by the interpolation point setting processing unit 25, and obtains the border of the influence range of ESD on the multiple designated electric components. The display control unit 26 then causes the obtained border of the influence range, to be display-output on the display unit 50 (Step S5).

(4-2) Procedure of Initialization Processing

Next, the procedure of the initialization processing of the present embodiment (refer to the processing of Step S2 in FIG. 12) will be described, with reference to the flowchart depicted in FIG. 13 (Steps S21-S23).

The initialization processing unit 21 sets multiple sample points on one or more designated electric components, and on multiple different components other than the designated electric components. The initialization processing unit 21 then generates a visible graph between the multiple sample points set on the designated electric components and the multiple different components (Step S21; refer to the bottom panel in FIG. 9 and the above-described processing (a1)).

The initialization processing unit 21 also divides each of the multiple different components, into multiple meshes, e.g., multiple triangle polygons (Step S22). In this step, the center of gravity G of each triangle is calculated (refer to the top panel in FIG. 9 and the above-described processing (a2)).

The initialization processing unit 21 then initializes the charge transfer distance for each component (Step S23). Specifically, the initialization processing unit 21 sets zero to the apices and sample points on the electric components specified by the user, as the initial value of the charge transfer distance (refer to the above-described processing (a3)). The initialization processing unit 21 also sets +∞ (maximum value) to each of sample points on each different component and the respective centers of gravity G of the multiple meshes on each different component, as the initial value of the charge transfer distance (refer to the above-described processing (a4)).

(4-3) Procedure of Charge Transfer Distance Calculation Processing

Next, the procedure of the charge transfer distance calculation processing of the present embodiment (refer to the processing of Step S3 in FIG. 12) will be described, with reference to the flowchart depicted in FIG. 14 (Steps S31-S33).

In the charge transfer distance calculation processing of Step S3 in FIG. 12, processing of Steps S31-S33 in FIG. 14 is executed on each of one or more designated electric components.

Specifically, as described above with reference to FIGS. 10A-10E, the on-surface distance calculation processing (Step S31) by the on-surface distance calculation processing unit 22 and the on-surface distance calculation processing (Step S32) by the space distance calculation processing unit 23 are repeatedly executed. Once processings of Step S31 and Step S32 are completed, the processing unit 20 determines whether or not at least one of the on-surface distance and the space distance has been updated in the current processing (Step S33). If so (the YES route from Step S33), the processing unit 20 returns to the processing of Step S31. Otherwise, if none of them have been updated (the NO route from Step S33), the processing unit 20 terminates the on-surface distance calculation processing and the space distance calculation processing on one designated electric component.

Note that the processing procedure of Step S31 by the on-surface distance calculation processing unit 22, and the processing procedure of Step S32 by the space distance calculation processing unit 23 will be described with reference to FIGS. 15 and 16, respectively.

(4-3-1) Procedure of on-Surface Distance Calculation Processing

Next, the procedure of the on-surface distance calculation processing of the present embodiment (refer to the processing of Step S31 in FIG. 14) will be described, with reference to the flowchart depicted in FIG. 15 (Steps S311-S319).

Initially, the on-surface distance calculation processing unit 22 receives component model data for one component, to at least one point of which a charge distance other than +∞ is set, from the product model data 32 (Step S311). After the check queue 36 is initialized, i.e., emptied (Step S312), the on-surface distance calculation processing unit 22 also enters information about the points to which a charge distance other than +∞ has been set, into the check queue 36 (Step S313).

Thereafter, the on-surface distance calculation processing unit 22 determines whether or not the check queue 36 is empty (Step S314). If it is empty (the YES route from Step S314), the processing unit 20 terminates the processing by the on-surface distance calculation processing unit 22 and transitions to the processing of Step S32 in FIG. 14. Otherwise, if it is not empty (the NO route from Step S314), the on-surface distance calculation processing unit 22 selects a first point of interest P (one point) by taking information related to the first point of interest P, out of the check queue 36 (Step S315; refer to the above-described processing (b1)).

The on-surface distance calculation processing unit 22 then extracts one of centers of gravity G adjacent to the selected first point of interest P, as a subsequent first point of interest, and executes processing in the following Steps S317-S319 on each extracted center of gravity G (Step S315; refer to the above-described processing (b2)).

In Step S317 (refer to the above-described processings (b3) and (b4)), the on-surface distance calculation processing unit 22 calculates a first sum of the charge transfer distance eDist(P) set to the first point of interest P and the first voltage attenuation associated with transfer from the first point of interest P to the subsequent first point of interest G. As set forth above, eDist(P) is the voltage corresponding to the shortest charge transfer distance at the point P. The first voltage attenuation associated with transfer from the first point of interest P to the subsequent first point of interest G is calculated based on the first voltage attenuation function F(x) or G(x) defining the voltage attenuation in accordance with charge transfer distance. Specifically, when the component where the point of interest is located is a conductor, the first voltage attenuation associated with transfer from the first point of interest P to the subsequent first point of interest G is calculated as F(|P−G|) and the first sum is eDist(P)+F(|P−G|). Otherwise, when the component where the point of interest is located is an insulator, the first voltage attenuation associated with transfer from the first point of interest P to the subsequent first point of interest G is calculated as G(|P−G|) and the first sum is eDist(P)+G(|P−G|). The on-surface distance calculation processing unit 22 then determines whether or not the calculated first sum eDist(P)+F(|P−G|) or eDist(P)+G(|P−G|) is less than the first voltage eDist(G) corresponding to the charge transfer distance that has been set to the subsequent first point of interest G.

If the first sum is less than the first voltage eDist(G) (the YES route from Step S317), the on-surface distance calculation processing unit 22 updates the first voltage eDist(G) set to the subsequent first point of interest G, with the first sum eDist(P)+F(|P−G|) or eDist(P)+G(|P−G|). In addition, the on-surface distance calculation processing unit 22 enters the subsequent first point of interest G into the check queue 36 (Step S318; refer to the above-described processing (b5)).

The on-surface distance calculation processing unit 22 then determines whether or not the determination in Step S317 has been made on all of the adjacent centers of gravity G (Step S319). If the determination has been made on all of the adjacent centers of gravity G (the YES route from Step S319), the on-surface distance calculation processing unit 22 returns to the processing of Step S314. If the determination has not been made on all of the adjacent centers of gravity G (the NO route from Step S319), the on-surface distance calculation processing unit 22 returns to the processing of Step S317.

Otherwise, if the first sum is equal to or greater than the first voltage eDist(G) (the NO route from Step S317), the on-surface distance calculation processing unit 22 transitions to the processing of Step S319.

In this manner, processings of Steps S317-S319 are repeatedly executed until a positive (YES) determination is made in Step S319. Furthermore, the processings of Steps S314-S319 are repeatedly executed until no information about a candidate for the first point of interest P is queued in the check queue 36, that is, the check queue 36 becomes empty.

(4-3-2) Procedure of Space Distance Calculation Processing

Next, the procedure of the space distance calculation processing of the present embodiment (refer to the processing of Step S32 in FIG. 14) will be described, with reference to the flowchart depicted in FIG. 16 (Steps S321-S329).

Initially, the space distance calculation processing unit 23 receives component model data for one component from the product model data 32 (Step S321). After the check queue 36 is initialized, i.e., emptied (Step S322), the space distance calculation processing unit 23 also enters information about the sample points to which a charge distance other than +∞ has been set, into the check queue 36 (Step S323).

Thereafter, the space distance calculation processing unit 23 determines whether or not the check queue 36 is empty (Step S324). If it is empty (the YES route from Step S324), the processing unit 20 terminates the processing by the space distance calculation processing unit 23, and transitions to the processing of Step S33 in FIG. 14. Otherwise, if it is not empty (the NO route from Step S324), the space distance calculation processing unit 23 selects a second point of interest P (one sample point) by taking information related to the second point of interest P, out of the check queue 36 (Step S325; refer to the above-described processing (c1)).

The space distance calculation processing unit 23 then extracts one of sample points connected to the selected second point of interest P in the visible graph, as a subsequent second point of interest Q, and executes processing in the following Steps S327-S329 on each extracted sample point Q (Step S325; refer to the above-described processing (c2)).

In Step S327 (refer to the above-described processings (c3) and (c4)), the space distance calculation processing unit 23 calculates a second sum of the charge transfer distance eDist(P) set to the second point of interest P and the second voltage attenuation associated with transfer from the second point of interest P to the subsequent second point of interest Q. As set forth above, the second voltage attenuation associated with transfer from the second point of interest P to the subsequent second point of interest Q is calculated based on the second voltage attenuation function H(x) defining the voltage attenuation in accordance with charge transfer distance that has been preset for each inter-component space. In other words, the second voltage attenuation associated with transfer from the second point of interest P to the subsequent second point of interest Q is calculated as H(|P−Q|) and the second sum is eDist(P)+H(|P−Q|). The space distance calculation processing unit 23 then determines whether or not the calculated second sum eDist(P)+H(|P−Q|) is less than the second voltage eDist(Q) corresponding to the charge transfer distance that has been set to the subsequent second point of interest Q.

If the second sum is less than the second voltage eDist(Q) (the YES route from Step S327), the space distance calculation processing unit 23 updates the second voltage eDist(Q) set to the subsequent second point of interest Q, with the second sum eDist(P)+H(|P−Q|). The space distance calculation processing unit 23 also enters the subsequent second point of interest Q into the check queue 36 (Step S328; refer to the above-described processing (c5)).

The space distance calculation processing unit 23 then determines whether or not the determination in Step S327 has been made on all of the connected sample points Q (Step S329). If the determination has been made on all of the connected sample points Q (the YES route from Step S329), the space distance calculation processing unit 23 returns to the processing of Step S324. If the determination has not been made on all of the connected sample points Q (the NO route from Step S329), the space distance calculation processing unit 23 returns to the processing of Step S327.

Otherwise, if the second sum is equal to or greater than the second voltage eDist(Q)(the NO route from Step S327), the space distance calculation processing unit 23 transitions to the processing of Step S329.

In this manner, the processings of Steps S327-S329 are repeatedly executed until a positive (YES) determination is made in Step S329. Furthermore, the processings of Steps S324-S329 are repeatedly executed until no information about a candidate for the second point of interest P is queued in the check queue 36, that is, the check queue 36 becomes empty.

(4-4) Procedure of Charge Transfer Distance Synthesis Processing

Next, the procedure of the charge transfer distance synthesis processing of the present embodiment and interpolation point setting processing (refer to the processing of Step S4 in FIG. 12) will be described, with reference to the flowchart depicted in FIG. 17 (Steps S41-S48).

Initially, the synthesis processing unit 24 and the interpolation point setting processing unit 25 function when multiple designated electric components (target components) are entered and set by the user, and receive component model data related to a different component to which the shortest charge transfer distance has been set, from the product model data 32 (Step S41).

The synthesis processing unit 24 then compares, for each point (sample point and center of gravity), shortest charge transfer distances from the respective designated electric components set to that point, and selects and sets the smallest one from the multiple shortest charge transfer distances, as the shortest charge transfer distance for each point (Step S42). In this manner, as described above with reference to FIGS. 11A and 11B, the charge distances (shortest charge transfer distances) of multiple designated electric components are synthesized into a single value.

Thereafter, the interpolation point setting processing unit 25 compares designated electric components serving as a starting point of two shortest charge transfer distances that are respectively set to adjacent two points of the sample point and the centers of gravity (Step S43). If the two designated electric components are identical (the YES route from Step S44), the processing unit 20 transitions to the processing of Step S48.

Otherwise, if the two designated electric components are different (the NO route from Step S44), the interpolation point setting processing unit 25 generates a line connecting the adjacent two points (Step S45). As described above with reference to FIGS. 11A and 11B, the interpolation point setting processing unit 25 then determines the variation of the charge distance on the line for each designated electric component, and identifies a point where the charge distances match (Step S46). The interpolation point setting processing unit 25 designates that point where the charge distances match, as an interpolation point (refer to Points q1 and q2 in FIG. 11B) (Step S47).

Thereafter, the processing unit 20 determines whether or not the comparison processing of Step S43 has been completed on all of adjacent points (Step S48). If so (the YES route from Step S48), the processing unit 20 transitions to the processing of Step S5 in FIG. 12. If not (the NO route from Step S48), the processing unit 20 (the interpolation point setting processing unit 25) returns to the processing of Step S45.

(5) Advantageous Effects of the Present Embodiment

As set forth above, in accordance with the information processing apparatus 10 of the present embodiment provided with an ESD verification function, when one or more target components inside a product are specified on the display unit 50 displaying a device (product) to be verified, a charge transfer distance conducting from the target component to a different component is calculated. Then, the region where the calculated charge transfer distance falls within a predetermined value is identified, and the identified region is displayed on the display unit 50 as the influence range of ESD on the target components, as depicted in FIG. 8. When multiple target component are specified, the distribution of charge transfer distances from the respective target component is determined for synthesis, and is displayed as the influence range of ESD on the multiple target components on the display unit 50.

In this manner, the user can see the influence range of ESD of the entire product, including the inside and outside of the product, at a glance, by watching a display on the display unit 50. Hence, the efficiency of an ESD verification is improved and man-hours required for the ESD verification are reduced while preventing any verification miss, i.e., miss of detection of problematic points, in a reliable manner which shortens the time required for the ESD verification. Further, since verification misses are prevented in a reliable manner, a reduction in the accuracy of ESD verification is no more experienced. Additionally, since the information processing apparatus 10 enables effective checks on anti-ESD measures while the design of the product is being modifying, the interactivity is enhanced and the efficiency of the anti-ESD measures are improved.

(6) Miscellaneous

While a preferred embodiment of the present invention has been described in detail, the present invention is not limited to that particular embodiment and may be practiced in a wide variety of modifications and variations, without departing from the spirit of the present invention.

For example, the example where two target components (designated electric components) are selected, has been described in the above-described embodiment, the present invention is not limited to this. A single target component (designated electric component) may be selected, or three or more target components (designated electric components) may be selected. Note that, when a single target component (designated electric component) is selected, the synthesis processing unit 24 and the interpolation point setting processing unit 25 do not function.

In accordance with one embodiment, the time of an electro-static discharge verification can be reduced.

All examples and conditional language provided herein are intended for the pedagogical purposes of aiding the reader in understanding the invention and the concepts contributed by the inventor to further the art, and are not to be construed limitations to such specifically recited examples and conditions, nor does the organization of such examples in the specification relate to a showing of the superiority and inferiority of the invention. Although one or more embodiments of the present inventions have been described in detail, it should be understood that the various changes, substitutions, and alterations could be made hereto without departing from the spirit and scope of the invention.

What is claimed is:

1. A non-transitory computer-readable storage medium having an electro-static discharge verification program stored therein, the discharge verification program causing a computer adapted to verify electro-static discharge in a verified device through a simulation, to execute processing to:
calculate a charge transfer distance of a charge conducting from a target component to a different component in the verified device,
obtain a region where the calculated charge transfer distance falls within a predetermined value, and
output the obtained region as an influence range of the electro-static discharge on the target component.

2. The non-transitory computer-readable storage medium according to claim 1, wherein the electro-static discharge verification program causes the computer to execute processing to:
extract a path having a lowest voltage attenuation, as a charge transfer path through which the charge transfers from the target component to a point of interest in the verified device; and
calculate the voltage attenuation associated with charge transfer of the charge through the path, as a voltage corresponding to the charge transfer distance from the target component to the point of interest.

3. The non-transitory computer-readable storage medium according to claim 2,
wherein the electro-static discharge verification program causes the computer to execute initialization processing to:
generate a visible graph among a plurality of sample points that are set on the target component and on a plurality of the different components;
divide each of the plurality of different components into a plurality of meshes;
set zero to apices on the target component and the sample points, as an initial value for the charge transfer distance; and
set a maximum value to the sample points on each different component and to the respective centers of gravity of the plurality of meshes on each different component, as an initial value for the charge transfer distance,
the electro-static discharge verification program causes the computer to execute on-surface distance calculation processing to:
select one of points corresponding to the apices on the target component and the respective centers of gravity of the plurality of meshes, to which a non-maximum value is set as the charge transfer distance, as a first point of interest on each of the different components;
extract one of the centers of gravity adjacent to the selected first point of interest, as a subsequent first point of interest;
calculate a first sum of the charge transfer distance set to the first point of interest and a first voltage attenuation associated with charge transfer from the first point of interest to the subsequent first point of interest;
determine whether or not the calculated first sum is less than a first the voltage corresponding to the charge transfer distance set to the subsequent first point of interest; and
update the first voltage set to the subsequent first point of interest with the first sum when the first sum is less than the first voltage,
the electro-static discharge verification program causes the computer to execute space distance calculation processing to:
select one of the apices on the target component and the plurality of sample points, to which a non-maximum value is set as the charge transfer distance, as a second point of interest in the verified device;
extract one of the sample points connected to the selected second point of interest in the visible graph, as a subsequent second point of interest,
calculate a second sum of the charge transfer distance set to the second point of interest and a second voltage attenuation associated with charge transfer from the second point of interest to the subsequent second point of interest;
determine whether or not the calculated second sum is less than a second the voltage corresponding to the charge transfer distance set to the subsequent second point of interest; and
update the second voltage set to the subsequent second point of interest with the second sum when the second sum is less than the second voltage, and
the electro-static discharge verification program causes the computer to repeatedly execute the on-surface distance calculation processing and the space distance calculation processing until neither the first voltage nor the second voltage is updated anymore.

4. The non-transitory computer-readable storage medium according to claim 3, wherein the electro-static discharge verification program causes the computer to execute processing to calculate the first voltage attenuation associated with the charge transfer from the first point of interest to the subsequent first point of interest, based on a first voltage attenuation function defining a voltage attenuation in accordance with the charge transfer distance, the first voltage attenuation function being preset for each of the different components.

5. The non-transitory computer-readable storage medium according to claim 3, wherein the electro-static discharge verification program causes the computer to execute processing to calculate the second voltage attenuation associated with the charge transfer from the second point of interest to the subsequent second point of interest, based on a second voltage attenuation function defining a voltage attenuation in accordance with the charge transfer distance, the second voltage attenuation function being preset for each of respective spaces between the different components.

6. The non-transitory computer-readable storage medium according to claim 3,
wherein the electro-static discharge verification program causes the computer to execute the initialization processing, the on-surface distance calculation processing, and the space distance calculation processing, for each of the plurality of target components,
the electro-static discharge verification program causes the computer to execute synthesis processing to:
select a shortest transfer distance among the plurality of charge transfer distances set for the respective plurality of target components to each point of the plurality of sample points and the respective centers of gravity of the plurality of meshes; and
set the selected shortest transfer distance to the each point, and
the electro-static discharge verification program causes the computer to execute the processing to:
derive a distribution of the charge transfer distance based on the shortest transfer distance set to the each point by the synthesis processing; and
determine and output the influence range of the electro-static discharge.

7. The non-transitory computer-readable storage medium according to claim 6,
wherein the electro-static discharge verification program causes the computer to execute interpolation point setting processing to set, when the two shortest transfer distances set to the adjacent two points of each of the points are respective distances from two different target components of the plurality of target components, a point on the line connecting those two points, where the charge transfer distances from the two different target component match, as an interpolation point,
the electro-static discharge verification program causes the computer to execute processing to:
derive a distribution of the charge transfer distance based on the shortest transfer set to the each point by the synthesis processing and the interpolation point set by the interpolation point setting processing; and
determine and output the influence range of the electro-static discharge.

8. An information processing apparatus comprising:
a processing unit adapted to verify electro-static discharge in a verified device through a simulation, processor being adapted to:
calculate a charge transfer distance of a charge conducting from a target component to a different component in the verified device,
obtain a region where the calculated charge transfer distance falls within a predetermined value, and
output the obtained region as an influence range of the electro-static discharge on the target component.

9. The information processing apparatus according to claim 8, wherein the processing unit is adapted to:
extract a path having a lowest voltage attenuation, as a charge transfer path through which the charge transfers from the target component to a point of interest in the verified device; and
calculate the voltage attenuation associated with charge transfer of the charge through the path, as a voltage corresponding to the charge transfer distance from the target component to the point of interest.

10. The information processing apparatus according to claim 9, wherein the processing unit comprises:
an initialization unit adapted to:
generate a visible graph among a plurality of sample points that are set on the target component and on a plurality of the different components;
divide each of the plurality of different components into a plurality of meshes;
set zero to apices on the target component and the sample points, as an initial value for the charge transfer distance; and
set a maximum value to the sample points on each different component and to the respective centers of gravity of the plurality of meshes on each different component, as an initial value for the charge transfer distance,
an on-surface distance calculation unit adapted to:
select one of points corresponding to the apices on the target component and the respective centers of gravity of the plurality of meshes, to which a non-maximum value is set as the charge transfer distance, as a first point of interest on each of the different components;
extract one of the centers of gravity adjacent to the selected first point of interest, as a subsequent first point of interest;
calculate a first sum of the charge transfer distance set to the first point of interest and a first voltage attenuation associated with charge transfer from the first point of interest to the subsequent first point of interest;
determine whether or not the calculated first sum is less than a first the voltage corresponding to the charge transfer distance set to the subsequent first point of interest; and
update the first voltage set to the subsequent first point of interest with the first sum when the first sum is less than the first voltage,
a space distance calculation unit adapted to:
select one of the apices on the target component and the plurality of sample points, to which a non-maximum value is set as the charge transfer distance, as a second point of interest in the verified device;
extract one of the sample points connected to the selected second point of interest in the visible graph, as a subsequent second point of interest,
calculate a second sum of the charge transfer distance set to the second point of interest and a second voltage attenuation associated with charge transfer from the second point of interest to the subsequent second point of interest;
determine whether or not the calculated second sum is less than a second the voltage corresponding to the charge transfer distance set to the subsequent second point of interest; and
update the second voltage set to the subsequent second point of interest with the second sum when the second sum is less than the second voltage, and
the processing unit repeatedly executes processing by the on-surface distance calculation unit and processing by the space distance calculation unit until neither the first voltage nor the second voltage is updated anymore.

11. The information processing apparatus according to claim 10, wherein the on-surface distance calculation processing unit is adapted to calculate the first voltage attenuation associated with the charge transfer from the first point of interest to the subsequent first point of interest, based on a first voltage attenuation function defining a voltage attenuation in accordance with the charge transfer distance, the first voltage attenuation function being preset for each of the different components.

12. The information processing apparatus according to claim 10, wherein the space distance calculation processing unit is adapted to calculate the second voltage attenuation associated with the charge transfer from the second point of interest to the subsequent second point of interest, based on a second voltage attenuation function defining a voltage attenuation in accordance with the charge transfer distance, the second voltage attenuation function being preset for each of respective spaces between the different components.

13. The information processing apparatus according to claim 10,
wherein the processing unit is adapted to execute processings by the initialization processing unit, the on-surface distance calculation processing unit, and the space distance calculation processing unit, for each of the plurality of target components,
the processing unit comprises a synthesis unit adapted to:
select a shortest transfer distance among the plurality of charge transfer distances set for the respective plurality of target components to each point of the plurality of sample points and the respective centers of gravity of the plurality of meshes; and
set the selected shortest transfer distance to the each point, and
the processing unit is adapted to:
derive a distribution of the charge transfer distance based on the shortest transfer distance set to the each point by the synthesis unit; and
determine and output the influence range of the electro-static discharge.

14. The information processing apparatus according to claim 13,
wherein the processing unit comprises interpolation point setting processing unit adapted to set, when the two shortest transfer distances set to the adjacent two points of each of the points are respective distances from two different target components of the plurality of target components, a point on the line connecting those two points, where the charge transfer distances from the two different target component match, as an interpolation point,
the processing unit is adapted to:
derive a distribution of the charge transfer distance based on the shortest transfer set to the each point by the synthesis processing unit and the interpolation point set by the interpolation point setting processing unit; and
determine and output the influence range of the electro-static discharge.

15. A method of verifying electro-static discharge in a verified device through a simulation by a computer, the method comprising:
calculating a charge transfer distance of a charge conducting from a target component to a different component in the verified device,
obtaining a region where the calculated charge transfer distance falls within a predetermined value, and
outputting the obtained region as an influence range of the electro-static discharge on the target component.

16. The method according to claim 15, comprising:
extracting a path having a lowest voltage attenuation, as a charge transfer path through which the charge transfers from the target component to a point of interest in the verified device; and
calculating the voltage attenuation associated with charge transfer of the charge through the path, as a voltage corresponding to the charge transfer distance from the target component to the point of interest.

17. The method according to claim 16, comprising:
executing execute initialization processing to:
generate a visible graph among a plurality of sample points that are set on the target component and on a plurality of the different components;
divide each of the plurality of different components into a plurality of meshes;
set zero to apices on the target component and the sample points, as an initial value for the charge transfer distance; and
set a maximum value to the sample points on each different component and to the respective centers of gravity of the plurality of meshes on each different component, as an initial value for the charge transfer distance;
executing on-surface distance calculation processing to:
select one of points corresponding to the apices on the target component and the respective centers of gravity of the plurality of meshes, to which a non-maximum value is set as the charge transfer distance, as a first point of interest on each of the different components;
extract one of the centers of gravity adjacent to the selected first point of interest, as a subsequent first point of interest;
calculate a first sum of the charge transfer distance set to the first point of interest and a first voltage attenuation associated with charge transfer from the first point of interest to the subsequent first point of interest;
determine whether or not the calculated first sum is less than a first the voltage corresponding to the charge transfer distance set to the subsequent first point of interest; and
update the first voltage set to the subsequent first point of interest with the first sum when the first sum is less than the first voltage;
executing space distance calculation processing to:
select one of the apices on the target component and the plurality of sample points, to which a non-maximum value is set as the charge transfer distance, as a second point of interest in the verified device;
extract one of the sample points connected to the selected second point of interest in the visible graph, as a subsequent second point of interest,
calculate a second sum of the charge transfer distance set to the second point of interest and a second voltage attenuation associated with charge transfer from the second point of interest to the subsequent second point of interest;
determine whether or not the calculated second sum is less than a second the voltage corresponding to the charge transfer distance set to the subsequent second point of interest; and
update the second voltage set to the subsequent second point of interest with the second sum when the second sum is less than the second voltage; and
repeatedly executing the on-surface distance calculation processing and the space distance calculation processing until neither the first voltage nor the second voltage is updated anymore.

18. The method according to claim 17, comprising:
calculating the first voltage attenuation associated with the charge transfer from the first point of interest to the subsequent first point of interest, based on a first voltage attenuation function defining a voltage attenuation in accordance with the charge transfer distance, the first voltage attenuation function being preset for each of the different components

19. The method according to claim 17, comprising:
calculating the second voltage attenuation associated with the charge transfer from the second point of interest to the subsequent second point of interest, based on a second voltage attenuation function defining a voltage attenuation in accordance with the charge transfer distance, the second voltage attenuation function being preset for each of respective spaces between the different components.

20. The method according to claim 17, comprising:
executing the initialization processing, the on-surface distance calculation processing, and the space distance calculation processing, for each of the plurality of target components;
executing synthesis processing to:
select a shortest transfer distance among the plurality of charge transfer distances set for the respective plurality of target components to each point of the plurality of sample points and the respective centers of gravity of the plurality of meshes; and
set the selected shortest transfer distance to the each point, and
deriving a distribution of the charge transfer distance based on the shortest transfer distance set to the each point by the synthesis processing; and
determining and output the influence range of the electro-static discharge.
